(19) United States
(12) Patent Application Publication
(10) Pub. No.: US 2005/0104081 A1
(43) Pub. Date: May 19, 2005

(54) Semiconductor light emitting diode and method for manufacturing the same

(76) Inventors: Seong-Jin Kim, Daejeon-Si (KR); Yong-Seok Choi, Gyeonggi-do (KR); Chang-Yen Kim, Chungcheongbuk-do (KR); Young-Heon Han, Chungcheongbuk-do (KR); Soon-Jae Yu, Gyeonggi-do (KR)

Correspondence Address: FULBRIGHT AND JAWORSKI L L P;PATENT DOCKETING 29TH FLOOR, 865 SOUTH FIGUEROA STREET, LOS ANGELES, CA, 900172576, US

(21) Appl. No.: 10/858,715

(22) Filed: Jun. 1, 2004

(30) Foreign Application Priority Data
Nov. 18, 2003 (KR) 2003-0081738
Dec. 30, 2003 (KR) 2003-0100016

(51) Int. Cl. H01L 33/00

(52) U.S. Cl. 257/99

(57) ABSTRACT

Provided is a light emitting diode including a base substrate having a via hole, a buffer layer having a via hole which is partially overlapped with the via hole of the base substrate, a first conductive contact layer formed on the buffer layer, a first clad layer formed on the second conductive contact layer, a light emitting layer formed on the first clad layer, a second clad layer formed on the light emitting layer, a second conductive contact layer formed on the second conductive clad layer, a first electrode formed on the second conductive contact layer, and a second electrode connected with the first conductive contact layer through the via hole.

### BACKGROUND OF THE INVENTION

(a) Field of the Invention

The present invention relates to a semiconductor light emitting diode and a method for manufacturing the same, using a sapphire substrate etching technique.

(b) Description of the Related Art

A light emitting diode is an optical device that emits light when a forward current passes through it. The early light emitting diodes had a p-n junction structure of semiconductors and used compounds such as indium phosphorus (InP), gallium arsenic (GaAs), gallium phosphorus (GaP), etc. to emit red or green light. Since then, various kinds of light emitting diodes emitting blue or ultraviolet light have been developed to be used for the purposes of displays, light source devices, and environmental application devices. Recently, a white light emitting diode generating white light using three chips of red, green, and blue or phosphors has been developed, and is widely utilized for illumination field applications.

In the case of using a light emitting substance of a nitride series for the thin layer of a light emitting diode, a sapphire, of which lattice constant and crystal structure are similar to those of nitride series, is used as the base substrate for preventing the crystal defects from being generated.

However, since the sapphire is an insulating material, both the first and second electrodes are formed on the grown surface of an epitaxial layer. In case both the electrodes are formed on the same surface, it is required to secure a space for the electrode required for wire bonding, such that a chip size of the light emitting diode increases.

Accordingly, the chip productivity per wafer is limited. Since the insulating material is used for the base substrate, it is difficult to discharge static electricity incoming from outside, resulting in an increase in the number of inferior chips. Using insulating base substrate induces many limitations in the manufacturing process. Due to the low thermal conductivity of Sapphire, heat which is produced during operation is not emitted well. Bad heat emitting disturbs applying a large current for high output power.

### SUMMARY OF THE INVENTION

The present invention has been made in an effort to solve the above problems.

It is an object of the present invention to provide a light emitting diode having a vertical electrode structure and a method for manufacturing the same using a sapphire substrate etching technique.

It is another object of the present invention to provide a simplified process of manufacturing a light emitting diode having a vertical electrode structure.

To achieve the above objects the present invention proposes the light emitting diode as following.

Provided is a light emitting diode including a base substrate having a via hole formed by partially or entire etching out a surface of the base substrate, a first conductive contact layer formed on the base substrate, a first conductive clad layer formed on the first conductive contact layer, a light emitting layer formed on the first conductive clad layer, a second conductive clad layer formed of the light emitting layer, a second conductive contact layer formed on the second conductive clad layer, a first electrode formed on the second conductive contact layer, and a second electrode connected to the first conductive contact layer through the via hole.

The light emitting diode further includes a buffer layer formed between the base substrate and the first conductive contact layer and having a via hole at least partially corresponding with the via hole of the base substrate, a first reflection and ohmic layer formed between the first electrode and the second conductive contact layer, and a second reflection and ohmic layer formed between the second electrode and the first conductive contact layer. Also, the second electrode is expanded outside the via hole so as to form a pad on the base substrate, the first electrode is formed as a single layer or multiple layers including at least one of Ni, Cr, Rh, Pd, Au, Ti, Pt, Au, Ta, and Al, and the second electrode is formed as a single layer or multiple layers including at least one of Ti, Al, Rh, Pt, Ta, Ni, Cr, Au. Also, the second electrode has a plurality of branches extending radial direction from a center.

Here, preferably the buffer layer is formed with Inₓ(Ga_{y}Al_{1-y})N, a composite ration of the Inₓ(Ga_{y}Al_{1-y})N is 1≧x≧0, 1≧y≧0. Also, the base substrate is formed by sapphire, the thickness of the base substrate is between 10 um and 500 um, and the surface of the base substrate without thin films is preferably polished to have roughness below 10 um.

Also, the first conductive contact layer is n-type, the second conductive contact layer is p-type, the via hole formed with the base substrate and the buffer layer becomes narrow as getting close to the first conductive contact layer, and a surface of the base substrate, on which the thin film is not formed, is provided with prominences and depressions.

It is preferred that the unit length of the prominence and depression is over ¼n (n is a refraction index, so each depression means the refraction index of sapphire and each prominence means the refraction index of air) of the wavelength of the light emitted by the light emitting diode so as to have photonic crystal characteristic.

Also, the first electrode is bonded on a lead frame by means of a conductive paste and the second electrode is electrically connected to the lead frame through a wire bonding.

The light emitting diode further includes a reflection and ohmic layer formed between the first electrode and the second conductive contact layer and a transparent conductive layer formed between the second electrode and the first conductive contact layer in such a manner that the via hole is expanded outside of the via hole so as to cover an area of a predetermined size of the base substrate, the transparent conductive layer being formed with at least one of ITO, ZrB, ZnO, InO, SnO, and Inₓ(Ga_{y}Al_{1-y})N.

The first electrode can be formed with a transparent conductive material and it is preferred to include a reflection and ohmic layer formed between the first conductive contact layer so as to cover the base substrate as well as inner surface of the via hole, the first electrode is preferably formed with at least one of ITO, ZrB, Zno, InO, SnO, and Inₓ(Ga_{y}Al_{1-y})N. In case of forming the first electrode with Inₓ(Ga_{y}Al_{1-y})N, the thickness is preferably formed at a thickness of from 0.1 um to 200 um.

Here, the buffer layer is preferably includes Inₓ(Ga_{y}Al_{1-y})N, the first electrode is provided with prominences and depressions formed in a net, and the light emitting diode can further include the first electrode pad formed on the first electrode and contacted with the second conductive contact layer. Also, the second electrode is bonded on a lead frame by means of a conductive paste, and the first electrode is electrically connected to a lead frame by means of a wire bonding.

The first electrode can be formed with a transparent electrode such as NiO and Ni/Au, the first electrode is formed with an ohmic layer and has a shape of net in order for the light transmitting, the base substrate has chamfered edges formed a surface opposite to the surface on which the buffer layer is formed, and the first and second conductive contact layer, the first and second clad layers, and the light emitting layer are preferably formed with Inₓ(Ga_{y}Al_{1-y})N (1≧x≧0, 1≧y≧0).

A method of manufacturing the light emitting diode includes forming, sequentially, a buffer layer, a first conductive contact layer, a first conductive clad layer, a light emitting layer, a second conductive clad layer, a second conductive contact layer, and a first electrode, lapping and polishing the base substrate, forming a protection layer on a surface of the first electrode and the base substrate, exposing some area of the surface of the base substrate by etching out the protection layer on the base substrate, forming a via hole by etching out the exposed surface of the base substrate and the buffer layer, forming second electrode connected to the first conductive contact layer through the via hole.

The method for manufacturing the light emitting diode further includes performing a thermal treatment in a furnace of an oxygen or nitrogen atmosphere at a temperature from 500□ to 700□ after the first electrode being deposited, and applying an auxiliary substrate before lapping and polishing the base substrate. Here, the auxiliary substrate can be one of a dielectric substrate such as sapphire, glass, and quartz, a semiconductor substrate such as Si, GaAs, InP, and InAs, a conductive oxide film substrate such as ITO, ZrB, and ZnO, and a metal substrate such CuW, Mo, Au, Al, and Au, the auxiliary substrate being preferably applied by means of wax as adhesive.

Also, as for lapping and polishing the base substrate, the base substrate is polished such that a roughness of the surface become below 1 um, and etching the protection layer on the base substrate is carried out by means of a wet etching technique using BOE solution as the etchant or an RIE dry etching technique.

Forming the via hole is carried out using a mixture solution, as an etchant, containing one or more among hydrochloric acid(HCl), nitric acid(HNO₃), potassium hydroxide(KOH), sodium hydroxide(NaOH), sulfuric acid(H₂SO₄), phosphoric acid (H₃PO₄), and Aluetch (4H₃PO₄+4CH₃COOH+HNO₃+H₂O), and the etchant is used at a temperature over 100□.

Also, forming a via hole is carried out using both of a wet etching technique using on or a mixture solution, as an etchant, among hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O), and a dry etching technique of ICP/RIE or RIE. The wet etching technique is used for etching out the base substrate and the dry etching technique is used for etching out the buffer layer, the buffer layer being formed with Inₓ(Ga_{y}Al_{1-y})N (1≧x≧0, 1≧y≧0) and being used as an etch stop layer. Whether or not the first conductive contact layer is exposed is determined by monitoring electric characteristic in the via hole using a probe and the dry etching technique uses at least one of BCl₃, Cl₂, HBr, and Ar, as an etching gas.

Preferably, the method further includes forming a first ohmic layer on the second conductive contact layer before depositing the first electrode; and forming a second ohmic layer contacting the first conductive contact layer before forming the second electrode, the first and second ohmic layers being able to have a light reflection characteristics according to the structure of the light emitting diode extracting light. Also, the first ohmic layer has a light reflection characteristic or the second ohmic layer is formed with a light penetrative conductive material.

Also, an opening exposing the second conductive contact layer is formed in the first electrode during the step of forming the first electrode and the first electrode being formed with a light transmitting conductive material and further comprises a step of a first electrode pad contacting the second conductive contact layer on the first electrode. At least one of the first electrode and the second electrode can be formed by means of electroplating technique and the electrode includes at least one of Ti, Au, Cu, Ni, Al, and Ag.

The first electrode and the second electrode can be formed by depositing NiO and NiAu and performing a thermal treating in an oxygen atmosphere at a temperature over 100° C., the first electrode is formed by growing Inₓ(Ga_{y}Al_{1-y})N at a thickness from 20 um to 200 um by VPE technique, the base substrate is preferably formed at the thickness between 0.50 um and 70 um while lapping and polishing the base substrate.

Lapping and polishing the base substrate are carried out by means of a wet etching technique using one or a mixture solution, as a etchant, of hydrochloric acid(HCl), nitric acid(HNO₃), potassium hydroxide(KOH), sodium hydroxide(NaOH), sulfuric acid(H₂SO₄), phosphoric acid(H₃PO₄) and Aluetch (4H₃PO₄+4CH₃COOH+HNO₃+H₂O) or chemical mechanical polishing. The method for manufacturing the light emitting diode further includes separating the base substrate into individual chips by performing at least one of a dry etching technique and a wet etching technique. Separating the base substrate is carried out by means of the wet etching technique using one or a mixture solution, as an etchant, of hydrochloric acid(HCl), nitric acid(HNO₃), potassium hydroxide(KOH), sodium hydroxide(NaOH), sulfuric acid(H₂SO₄), phosphoric acid(H₃PO₄), and Aluetch(4H₃PO₄+4CH₃COOH+HNO₃+H₂O). While forming the via hole by etching the exposed area of the base substrate, scribing lines for separating the base substrate into individual chips and prominences and depressions for facilitating light extraction are formed at the same time.

The method for manufacturing the light emitting diode further includes forming an etch stop layer at an area in which the via hole is formed before forming the buffer layer on the base substrate.

Also, the present invention provides a method for etching a sapphire substrate which includes growing a nitride semiconductor thin layer on the sapphire substrate and performing a wet etching by immersing the sapphire substrate into one or a mixture solution, as an etchant, of hydrochloric acid(HCl), nitric acid(HNO₃), potassium hydroxide(KOH), sodium hydroxide(NaOH), sulfuric acid(H₂SO₄), phosphoric acid(H₃PO₄), and Aluetch (4H₃PO₄+4CH₃COOH+HNO₃+H₂O).

Here, a method for etching a sapphire substrate includes etching the sapphire substrate by a dry etching with ICP/RIE technique, and the dry etching can be performed before the wet etching. Here, during the wet etching process the etchant of one or a mixture solution of hydrochloric acid (HCl), nitric acid (HNO₃), potassium hydroxide(KOH), sodium hydroxide (NaOH), sulfuric acid(H₂SO₄), phosphoric acid (H₃PO₄), and Aluetch (4H₃PO₄+4CH₃COOH+HNO₃+H₂O) is heated over 100° C. Preferably, the etchant is heated by an indirect heating technique using an optical absorption.

Provided is a method for manufacturing the light emitting diode including depositing, sequentially, a buffer layer, a first conductive contact layer, a light emitting layer, a second conductive clad layer, a second conductive contact layer, and a first electrode, applying an auxiliary substrate on the base substrate; partially or entirely removing the base substrate as much as a predetermined thickness by polishing or etching out the base substrate, and forming a second electrode electrically connected to the first conductive contact layer.

Here, the thickness of the base substrate after polishing or etching is preferably between 0.1 um and 250 um.

Provided is a light emitting diode including a conductive receptor substrate having a top and bottom surfaces, a first electrode formed on the bottom surface of the receptor substrate, a joint layer formed on the upper surface of the receptor substrate and having conductivity, a light reflection layer formed on the joint layer, a first clad layer formed on the light reflection layer, a light emitting layer formed on the first clad layer, a second clad layer forming on the light emitting layer, a second electrode formed on the second clad layer.

Here, the light emitting diode further includes a first receptor contact layer between the first electrode and the receptor substrate, a second receptor contact layer formed between the receptor substrate and the joint layer, a first conductive contact layer formed between the light reflection layer and the first clad layer, and a first conductive contact layer formed between the second clad layer and the second electrode.

Also, the light emitting diode further includes a conductive transparent electrode formed between the light reflection layer and the first conductive contact layer, and a second electrode ohmic layer formed between the second electrode and the second conductive contact layer.

The joint layer is formed with a metal including at least one of Ti, Ni, In, Pd, Ag, Au, and Sri, and the joint layer can be an epoxy film having conductivity.

Also, the first conductive contact layer is p-type, and the second conductive contact layer is n-type, the conductive receptor substrate is formed with at least on of a semiconductor substrate such as Si, GaP, InP, InAs, GaAs, and SiC, a metal substrate or a metal film such Au, Al, CuW, Mo, and W, the light reflection layer includes at least one of Ni, Al, Ag, Au, Cu, Pt, and Rh. The light emitting diode further include a buffer layer formed on the second conductive contact layer and a base substrate formed on the buffer layer, the base substrate being provided with a via hole. Preferably, the thickness of the sapphire substrate is in the range of 10 um to 300 um and the sapphire substrate has prominences and depressions on a surface so as to obtain a photonic crystal characteristic.

The light emitting diode is manufactured by depositing, sequentially, a buffer layer, a n-type contact layer, an active layer, a p-type contact layer on a sapphire, forming a first and a second receptor contact layers on respective opposite side of a receptor substrate, forming a joint layer at least on one of p-type contact layer and the second receptor contact layer, jointing the sapphire substrate and the receptor substrate by thermal-compressing in a state of facing the p-type contact layer and the second receptor contact layer with each other, lapping and polishing the base substrate, depositing an oxide film (SiO2) on the base substrate, exposing, partially, the base substrate by patterning and etching out the oxide film, forming a via hole by etching out the sapphire substrate, and forming a second electrode and a first electrode on the n-type contact layer and the first receptor contact layer, respectively. Here, manufacturing the light emitting diode further includes forming a conductive transparent electrode layer and a light reflection layer on the p-type contact layer before forming the joint layer on at least one of the p-type contact layer and the second receptor contact layer. Etching the sapphire substrate is carried out by means of at least one among a wet etching technique with one or a mixture solution, as an etchant, of hydrochloric acid (HCl), nitric acid (HNO₃), potassium hydroxide(KOH), sodium hydroxide (NaOH), sulfuric acid (H₂SO₄), phosphoric acid(H₃PO₄), and Aluetch (4H₃PO₄+4CH₃COOH+HNO₃+H₂O), a chemical mechanical polishing (CMP) technique, and ICP/RIE dry etching technique. Removing the sapphire substrate and the buffer layer is carried out by means of both the wet etching technique and the dry etching technique, the wet etching technique being used for etching out the sapphire substrate and the dry etching technique being used for etching out the buffer layer. Thermal-compressing is carried out in vacuum or in a gaseous atmosphere including at least one among Ar, He, Kr, Xe, and N2. Thermal-compressing is carried out at temperatures from 200□ to 600□ at a pressure between 1 MPa and 6 Mpa for 1˜60 minutes.

The light emitting diode is manufactured by depositing, sequentially, a buffer layer, a n-type contact layer, an active layer, a p-type contact layer on a sapphire, forming a first and a second receptor contact layers on respective opposite side of a receptor substrate, forming a joint layer at least on one of p-type contact layer and the second receptor contact layer, jointing the sapphire substrate and the receptor substrate by thermal-compressing in a state of facing the p-type contact layer and the second receptor contact layer with each other, lapping and polishing the base substrate, depositing an oxide film (SiO2) on the base substrate, exposing, partially, the base substrate by patterning and etching out the oxide film, forming a via hole by etching out the sapphire substrate, and forming a second electrode and a first electrode on the n-type contact layer and the first receptor contact layer, respectively.

Here, manufacturing the light emitting diode further includes further forming a conductive transparent electrode layer and a light reflection layer on the p-type contact layer before forming the joint layer on at least one of the p-type contact layer and the second receptor contact layer.

### BRIEF DESCRIPTION OF THE DRAWINGS

FIG. 1 is a sectional view illustrating a light emitting diode having the vertical electrode structure according to a first embodiment of the present invention.

FIG. 2 is a sectional view illustrating a light emitting diode chip having the vertical electrode structure according to the first embodiment of the present invention.

FIG. 3 is a top plan view illustrating the light emitting diode chip having the vertical electrode structure shown in the direction of the sapphire substrate according to the first embodiment of the present invention.

FIG. 4 is a top plan view illustrating a light emitting diode chip having a vertical electrode structure according to a second embodiment of the present invention.

FIG. 5 is a photograph of the surface of a sapphire substrate after forming a specific pattern on the sapphire substrate by means of wet etching with a mixture solution of sulfuric acid and phosphoric acid.

FIG. 6 is graph for illustrating the etching speed of the sapphire and GaN in the ICP/RIE dry etching.

FIG. 7 is a graph for illustrating the etching speeds of the sapphire and GaN by means of the wet etching technique with the mixture etchant of the sulfuric acid and phosphoric acid.

FIG. 8 is a photograph showing the buffer layer after the sapphire substrate is removed by means of the wet etching technique.

FIG. 9 is a graph showing the voltage-current characteristic curve of the nitride series semiconductor layer after the sapphire substrate is removed.

FIG. 10 is a sectional view illustrating a vertical electrode structure-type light emitting diode according to a third embodiment of the present invention.

FIG. 11 is a sectional view illustrating a vertical electrode-type light emitting diode according to the third embodiment of the present invention.

FIG. 12 is a plane view of a light emitting diode having the vertical electrode structure, shown on the sapphire substrate.

FIG. 13 is a sectional view illustrating a light emitting diode chip having the vertical electrode structure according to a fourth embodiment of the present invention.

FIG. 14 is a sectional view illustrating a light emitting diode having the vertical electrode structure according to a fifth embodiment of the present invention.

FIG. 15 is a sectional view illustrating a light emitting diode chip having the vertical electrode structure according to the fifth embodiment of the present invention.

FIG. 16 is a top plan view illustrating the light emitting diode chip shown on the first electrode according to the fifth embodiment of the present invention.

FIG. 17 is a sectional view illustrating a light emitting diode chip having the vertical electrode structure according to a sixth embodiment of the present invention.

FIG. 18 is a top plan view illustrating the light emitting diode chip having the vertical electrode structure according to the sixth embodiment of the present invention, shown in a direction of the first electrode.

FIG. 19 is a sectional view illustrating a light emitting diode having a vertical electrode structure according to a seventh embodiment of the present invention.

FIG. 20 is a sectional view for illustrating a middle stage of manufacturing the light emitting diode according to the seventh embodiment of the present invention.

FIG. 21 is a sectional view showing the next stage of FIG. 20 and illustrating how the electrode substrate is attached to the base substrate on which epitaxial layers and a contact layer are formed.

FIG. 22 is a sectional view showing the next stage of FIG. 21 and illustrating how the base substrate is removed.

FIG. 23 is a sectional view showing the next stage of FIG. 22 and illustrating how the first and second electrodes are formed.

FIG. 24 is a drawing illustrating a sectional profile of the n-type contact layer 15 and the light concentrating effect after removing the sapphire substrate by means of the back side lapping and etching techniques.

FIG. 25 is a sectional view illustrating a light emitting diode having the vertical electrode structure according to an eighth embodiment of the present invention.

### DETAILED DESCRIPTION OF THE PREFERRED EMBODIMENTS

In the drawings, the thickness of layers, films and regions are exaggerated for clarity. Like numerals refer to like elements throughout. It will be understood that when an element such as a layer, film, region or substrate is referred to as being “on” another element, it can be directly on the other element or intervening elements may also be present. In contrast, when an element is referred to as being “directly on” another element, there are no intervening elements present.

A light emitting diode having a vertical electrode structure according to the present invention will be described hereinafter with reference to the accompanying drawings.

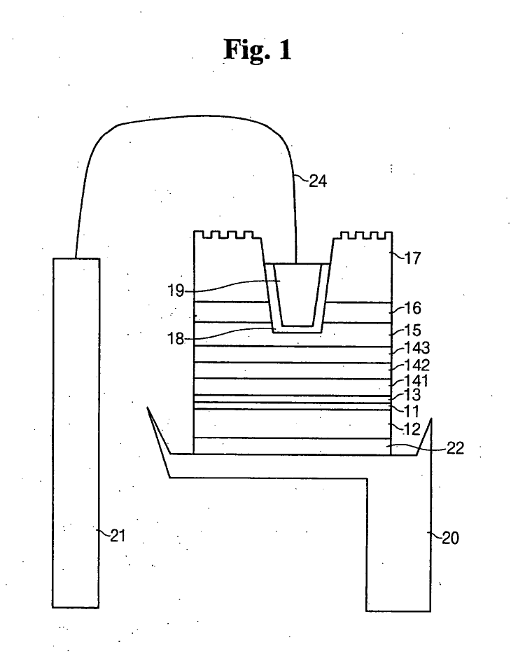

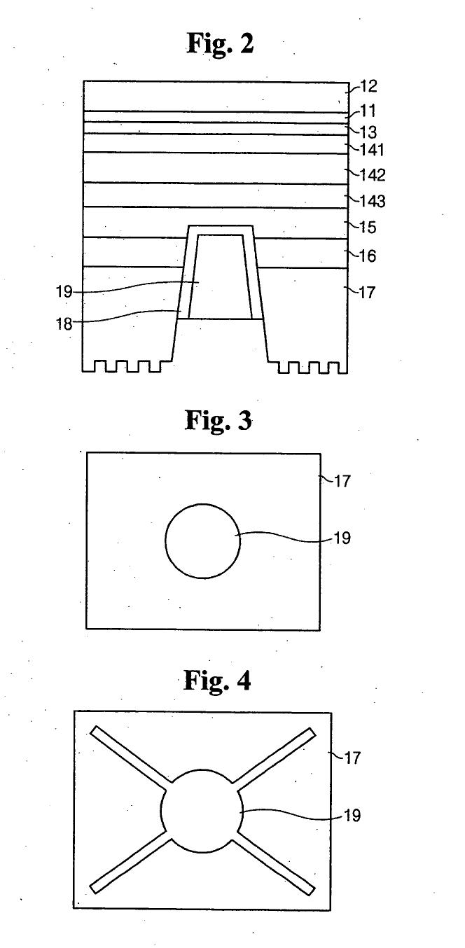

FIG. 1 is a sectional view illustrating a light emitting diode having a vertical electrode structure according to a first embodiment of the present invention, FIG. 2 is a sectional view illustrating a light emitting diode chip having the vertical electrode structure according to the first embodiment of the present invention, and FIG. 3 is a top plan view illustrating the light emitting diode chip having the vertical electrode structure shown in the direction of the sapphire substrate according to the first embodiment of the present invention.

The light emitting diode according to the preferred embodiment of the present invention includes a lead frame 20 and 21, a chip adhered to the lead frame 20 and 21, a conductive paste 22 to adhere the chip to the lead frame 20, and a wire 24 for connecting an electrode of the chip to the lead frame 21.

The chip is formed in such a way that a buffer layer 16, an n-type contact layer 15, a n-type clad layer 143, a light emitting layer 142, a p-type clad layer 141, a p-type contact layer 13, a first ohmic and light reflection layer 11, and a first electrode 12 are deposited on a sapphire substrate 17 in that order, and a second ohmic layer 18 and a second electrode 1.9 are formed inside a via hole which penetrates the sapphire substrate 17 and the buffer layer 16.

Here, the second ohmic layer 18 partially coats the inner surface of the via hole and contacts the n-type contact layer 15, and the second electrode 19 is formed so as to fill the via hole to a predetermined depth. In order to facilitate the light emittion and to prevent the electrode from being broken during forming the electrode, the via hole is preferably formed such that its diameter gradually decreases as it goes down. Also, the horizontal sectional surface of the via hole can be modified so as to have a shape of circle, square, etc., and the number of the via holes can be one or more.

The thickness of the sapphire substrate 17 is in the range of 10 um to 300 um, and is preferably between 40 um and 150 um.

The surface of the sapphire substrate 17 has prominences and depressions. The unit length of prominence and depression are preferably greater than ¼n (“n” is refraction index. For the depression, “n” is the refraction index of sapphire and for the prominence, “n” is the refraction index of air) so as the prominence and depression to have photonic crystal characteristics. The prominence and depression control the direction of light to progress toward the normal direction of the sapphire substrate 17 by total reflection. It is preferable that the depth of the depression is greater than 1 um. The depression may be preferably greater than 5 um to increase efficiency of light emitting by increasing the critical angle of total reflection. The depth of the depression may range from 0.1 um˜50 um.

The first electrode 12 is made of at least one of Ni, Cr, Rh, Pd, Au, Ti, Pt, Ta, Al, and an alloy of some of these materials, and the buffer layer 16 and n- and p-types contact layers 15 and 13 are made of Inₓ(Al_{y}Ga_{1-y})N. Here, x and y range from 0 to 1. The first ohmic and light reflection layer 11 is preferably made of one of Pt, Ni, and their alloys which are robust against acids, and have excellent adhesiveness to SiO₂ for preventing damage during the wet etching process. It is especially preferable that the first ohmic and light reflection layer 11 is made of one of Pt, Ni/Pt, Ni/Ti/Pt, Ni/Au/Ni, etc.

The n-type contact layer 15 is doped with Si dopants of which concentration is greater than 10¹⁸atoms/cm³, and the p-type contact layer 13 is doped with Mg dopant of which concentration is greater than 10¹⁸ atoms/cm³ in order to make the contact specific resistance less than 1×10⁻¹ .Ωcm.

Also, the second electrode 19 is made of one of Ti, Al, Rh, Pt, Ta, Ni, Cr, Au, and an alloy of some of these materials. It is especially preferable that the second ohmic 18 and the second electrode 19 are made of one of Ni/Ti/Au, Ti/Ni/Au, Ni/Au, Ti/Au, or Ti/Al. The second electrode 19 can be deposited together with the second ohmic layer 18 or can be deposited after deposition of the second ohmic layer 18. It is preferable that the second electrode 19 has a metal structure including Au so as to facilitate wire bonding in a package process.

The n-type and p-type clad layers 143 and 141 and the light emitting layer 142 are made of Inₓ(Ga_{y}Al_{1-y})N, wherein the composition rates of x and y are 1≧x≧0, 1≧y≧0. That is, the n-type and p-type clad layers 143 and 141 and the light emitting layer 142 can be made of GaN, AlGaN, InGaN, AlGaInN, etc. The light emitting layer 142 can be formed to have a single quantum well or a multiple quantum well structure which are formed by barrier and well layers of Inₓ(Ga_{y}Al_{1-y})N. The light emitting layer 142 may be doped with Si so as to reduce the operating voltage of the light emitting diode. Also, by adjusting the composition rate of the In, Ga, and Al in the light emitting layer 142, it is possible to manufacture a various light emitting diode emitting light from long wavelengths of InN(˜2.2 eV) band gaps to short wavelengths of AlN(˜6.4 eV).

The first ohmic and light reflecting layer 11 can be formed with single or multiple layers. In this embodiment, the first ohmic and light reflecting layer 11 is formed with a mixture including one or more among Pt, Ni, Rh, Au, and Ag, etc. The light reflectivity of the first ohmic and light reflecting layer 11 is preferably greater than 50% for enhancement of brightness.

In this structure, the light generated at the light emitting layer 142 is emitted through the sapphire substrate 17.

In the above-structured light emitting diode, the first and second electrodes 12 and 19 are separately formed on the respective upper and lower surfaces of the chip such that it is possible to reduce the chip size. Accordingly, the productivity of chips per wafer dramatically increases. Also, the via hole is formed on the sapphire substrate 17 and the second electrode made of conductor and formed in the via hole efficiently discharge heat and static electricity so as to improve the reliability of the device.

Furthermore, the current flow over the whole horizontal section of the chip and the efficient heat discharge allows the chip to be operated with a high current such that it is possible to obtain high light output with a single device. Since these device satisfy the high brightness characteristic essentially required for application in an illumination and backlight unit of the liquid crystal display, it can be widely utilized.

FIG. 4 is a top plan view illustrating the light emitting diode chip having a vertical electrode structure according to a second embodiment of the present invention.

As shown in FIG. 4, the second electrode 19 is branched outside from the center circle so as to improve the current distribution and thermal emission in the second embodiment. The plan view of the second electrode 19 can be modified in various shapes.

Now, a method of manufacturing a light emission diode having the above structure will be described.

The buffer layer 16, n-type contact layer 15, n-type clad layer 143, light emitting layer 142, p-type clad layer 141, and p-type contact layer 13 are deposited on the sapphire (Al₂O₃) substrate 17 in that order using any of metal organic chemical vapor deposition, liquid phase epitaxy, molecular beam epitaxy, hydride vapor phase epitaxy, metal organic vapor phase epitaxy (MOVPE), metal organic chemical vapor deposition, liquid phase epitaxy, molecular beam epitaxy, and vapor phase epitaxy.

Sequentially, the first ohmic and light reflection layer 11 is formed on the p-type contact layer 13, and the first electrode 12 is formed on the first ohmic layer and light reflection layer 11. Here, the first ohmic and light reflecting layer 11 of Rh/Au/Pt/Au, Ni/Au, Ni/Ti/Au, or Pt/Au and the first electrode 12 are formed using at least one of the E-Beam deposition, thermal evaporation, sputtering, etc. After the deposition of the first electrode 12, the ohmic contact is formed between the first electrode 12 and the first ohmic and light reflection layer 11 by performing heat treatment in a furnace filled with oxygen or nitrogen at a temperature between 300° C. and 700° C. (preferably between 400° C. and 600° C.) so as to decrease the contact resistance with the semiconductor layer.

Next, any one of dielectric substrate such as a sapphire, a glass, and a quartz; a semiconductor substrate such as Si, GaAs, InP, and InAs; and a conductive oxide film substrate such as Indium Tin Oxide (ITO), ZrB, and ZnO is attached on the first electrode 12 as an auxiliary substrate (not shown).

The auxiliary substrate may be attached by using wax as a bonding agent so as to be easily detached after processing. Sometimes, the auxiliary substrate may be attached by an adhesion layer of eutectic metal made of at least one of Ni, Ti, Au, Pt, In, Pd, Ag, and Sn. In the latter case, the attached substrate becomes a part of the chip rather than is removed. In the case of using the eutectic metal as the adhesion layer, the sapphire substrate 17 is wholly or partially etched in order to expose the buffer layer.

When the sapphire substrate 17 is attenuated or completely removed, the auxiliary substrate is play a role of a support of the chip and a passage of the current rather than is removed. In this case, the auxiliary substrate becomes a receptor substrate.

The reason of using the auxiliary substrate is in order to facilitate substrate handling during processes such as polishing the sapphire substrate thin enough in order to reduce the time of etching the sapphire for forming via hole. Using the auxiliary substrate is helpful to increase the yield.

When the auxiliary substrate becomes a receptor substrate, the auxiliary substrate is needed to have conductivity. Accordingly the auxiliary substrate is made of at least one of conductive semiconductors such as doped Si, GaAs, InP, and InAs; conductive non-metal materials such as ITO, ZrB, and ZnO; and metals such as CuW, Mo, Au, Al, and Au. When the auxiliary substrate becomes a receptor substrate, the auxiliary substrate is tightly bonded by thermo compression bonding using the eutectic metal such as Ni, Ti, Au, Pt, In, Pd, Ag, and Sn. Here, the bonding process is performed under a pressure between 1 MP and 6 MP and at a temperature of 200° C.˜600° C. for 1˜60 minutes.

Particularly, in the case of using a metal as the auxiliary substrate, the metal substrate can be attached by thermo compression bonding or can be formed by plating with one of Ag, Au, Cu, Pt, Ni, and their mixture. The plating can be carried out by an electroplating or an electroless plating technique. The plated metal layer preferably has a thickness greater than 1 um to be used as an auxiliary substrate.

Next, after a protection layer such as spin-on glass (SOG), SiNx, and SiO₂ is deposited on the p-type contact layer 13 in a thickness of 1 um in order to protect the surface of the semiconductor during the wet or dry etching process, the sapphire substrate 17 is lapped and polished to have a mirror like surface.

The lapping of the sapphire substrate is performed by one or more methods among chemical mechanical polishing (CMP), inductive coupled plasma/reactive ion etching (ICP/RIE), dry etching, and machine grinding using alumina (A12O3) powder, and wet etching with an etchant made of one or mixture of hydrochloric acid (HCl), nitric acid (HNO3), potassium hydroxide (KOH), sodium hydroxide (NaOH), sulfuric acid (H2SO4), phosphoric acid (H3PO4), and Aluetch (4H3PO4+4CH3COOH+HNO3+H2O).

Here, the thickness of the sapphire substrate 17 is preferably formed to be quite thin, but if it is too thin it is likely to be easily bent and difficult to deal with. Therefore the sapphire substrate 17 is processed to a thickness of approximately 10 um˜300 um (preferably 50 um˜70 um). Also, the roughness of the surface of the polished sapphire substrate 17 should be less than 10 um. The roughness of the sapphire substrate 17 is transferred to the n-type contact layer 15 and the below layers during etching the sapphire substrate 17 and the buffer layer 16. Accordingly, if the roughness of the sapphire substrate 17 is too large, the layered structure of the light emitting diode may get damage by transfer of the roughness.

After the polishing process, the sapphire surface is cleaned and a protection layer such as SiNx or SiO2 is deposited on the surface of the sapphire substrate 17. An etching mask for forming prominences and depressions is then formed and the sapphire substrate 17 is etched such that the prominences and depressions are formed. Here, the protection layer should remain at the area where the via hole is to be formed such that the mirror surface of the via hole area is protected when etching the sapphire substrate 17.

The sapphire surface cleaning process is performed so as to remove the wax used in the polishing process, and is carried out by means of acetone cleansing, ultraviolet (UV) irradiation, or wet etching with a mixture solution comprising at least one among HCl, HNO3, KOH, NaOH, H2SO4, H3PO4, and Aluetch (4H3PO4+4CH3COOH+HNO3+H2O). Any wax remaining on the polished sapphire surface can deteriorate the cohesiveness of the protection film.

The protection film coated over the sapphire surface is removed after the formation of the prominences and depressions on the sapphire substrate 17, and then the protection layer is formed on the respective first electrode 12 and sapphire substrate 17 by depositing a silicate cement (SiO2) layer or coating a spin-on-glass (SOG) layer.

Sequentially, the SiO2 or SOG protection film is patterned by photo-etching so as to partially expose the sapphire substrate 17 to form a via hole therein. Here, the etching of the protection film is carried out by means of reactive ion etching (RIE) or with a buffer oxide etchant (BOE) solution.

The prominences and depressions of the surface of the sapphire can also be formed with the via hole at the same time. That is, since the etching depth of the sapphire is proportional to the size of the open area of the etching mask, the etching stops at an adequate depth by forming a wide open area on a place to be the via hole and a narrow open areas on places to be the depression. The wide open area is preferably wide enough to allow the buffer layer 16 under the sapphire substrate 17 being etched.

Also, it is possible to form a scribing line or cleaving line of the device when forming the via hole by using the wet etching characteristics of the sapphire substrate 17.

The wet etching of sapphire substrate progresses with some directional feature. Even though it is not depicted as an example, the sapphire base substrate used for growing the semiconductor thin film of a nitride series has a C-facet of (0001) such that the etched surface is formed to slant at an angle of 20 to 50 degrees with respect to the bottom surface. This is because the etching speed of the (0001) facet is different from that of the other etched facets such as M, A, and B facets. Accordingly, the etching depth varies according to the line width or area of the opening for etching, and if the etching progresses to some depth, etched section has a V-grooved shape so as to form the scribing line. The scribing line formed by wet etching is more clean and clear than a scribing line formed by diamond pen.

It is sufficient for the scribing line to have an etched depth of over 1 um. The scribing line is automatically formed since the etching stops at an adequate depth during the via hole etching such that it is possible to form the scribing line for separating the chip without an additional process. In the present invention, minute scribing lines for separating the chips are formed by one or more of the wet and dry etching techniques so as to make the cutting surface clear with a slope to facilitate the separation of the devices.

In the meantime, The sapphire substrate 17 is etched to a depth by means of ICP/RIE or RIE and is etched to penetrate the sapphire substrate 17 by immersing the sapphire substrate into a solution or a mixture solution of HCl, HNO3, KOH, NaOH, H2SO₄, H6PO₄, and Aluetch (4H₃PO₄+4CH₃COOH+HNO₃+H₂O) such that the via hole is completely formed. Using both of the dry and wet etching is for preventing horizontal section area ratio of top and bottom of the via hole from being too large. That is, the sapphire substrate 17 is etched by dry etching to a depth in order to form upper portion of the via hole having uniform the horizontal section area. After that, the sapphire substrate 17 is etched by wet etching in order to form below portion of the via hole having slanted side walls. It is preferred that a bottom-to-top section area ratio of the via hole is about 0.9, however, it is possible to manufacture the device with an opposite bottom-to-top surface ratio.

Next, the buffer layer 16 is etched by means of dry etching such as ICP/RIE or RIE technique so as to form the via hole exposing the n-type contact layer 15.

The wet etching for the sapphire substrate 17 is carried out as in the following procedure.

On the basis of a measured sapphire substrate etching speed, the sapphire substrate 17 is immersed for a certain time in which the sapphire substrate can be etched by more than the thickness deviation of the sapphire substrate 17.

The etchant has a characteristic in that its etching speed to the buffer layer 16 is 10 times slower than that to the sapphire substrate 17. That is, the etching selectivity ratio of the buffer layer 16 to the sapphire substrate 17 is equal to or greater than 10. Accordingly, the layers under the buffer layer 16 can be protected from damage while the sapphire substrate 17 is completely etched since the etching-out speed of the buffer layer 16 is slow enough.

In the meantime, it is preferred that the temperature of the etchant is maintained at over 100° C. In order to maintain the temperature of the etchant at over 100° C., two heating techniques can be used, i.e., direct heating in which the etchant is positioned on a heater or is contacted to the heater, and indirect heating using optical absorption with a halogen lamp.

The sapphire substrate 17 can be etched by ICP/RIE technique. Even though it is preferred to increase the power of the ICP and RIE to accelerate the etching speed on the sapphire substrate 17, when increasing the power of the ICP and RIE, careful process management is required to prevent the under layer from getting damage.

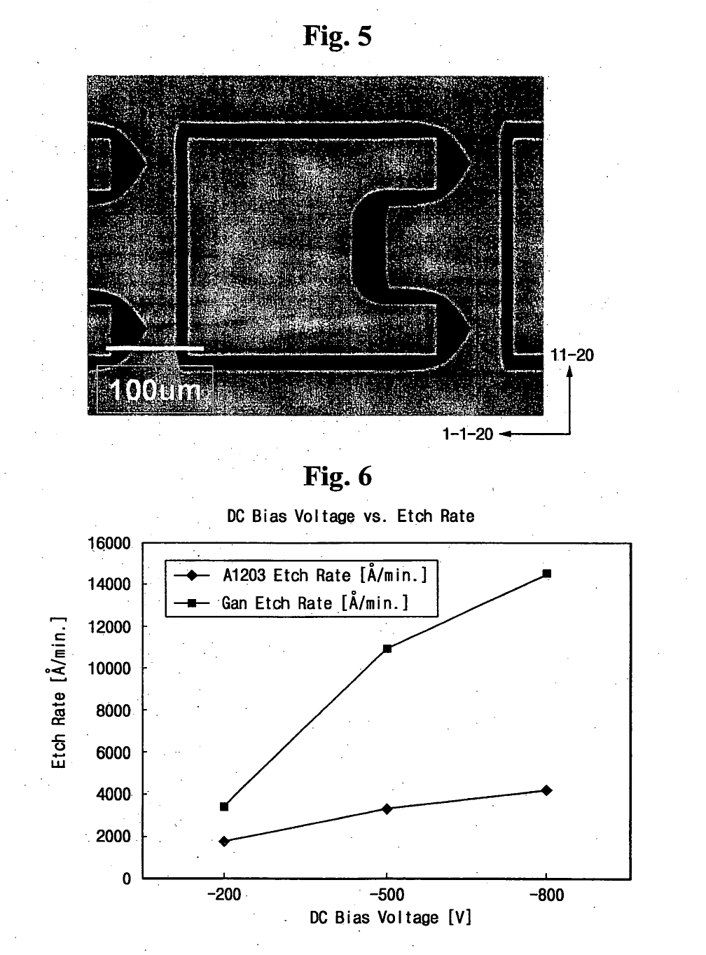

FIG. 5 is a photograph of the surface of the sapphire substrate 17 after forming a specific pattern thereon by means of an etching mask and then etching the sapphire substrate with a mixture solution of sulfuric acid and phosphoric acid.

As shown in FIG. 5, the etched side wall and sapphire substrate surfaces are smooth. The sapphire substrate 17 is etched out as much as 22.4 um in 20 minutes at the temperature of 330° C. The etching speed is 1.1 um/min. This etching speed is worthy of close attention and does not cause problems in consideration of mass production. The wet etching technique is advantageous in view of mass production in comparison with other techniques because a plurality of wafer can be wet etched at a time by one wet etching equipment.

In the case of adopting the present invention to mass production, it is important to secure the process conditions with which the etching selectivity ratio of the sapphire substrate 17 to the nitride series semiconductor is large enough. It is efficient way for mass production to use the nitride series semiconductor as an etch stopping layer. The nitride semiconductor layer made of Inₓ(Ga_{y}Al_{1-y})N series materials (1≧x≧0, 1≧y≧0) can be used as an etch stopping layer. It is preferable for etch stopping to increase the composition ratio of Al and to use p-Inx(GayAl1-y)N series materials doped with Mg in the concetration of 1×1017 cm−3.

When un-doped GaN, p-GaN doped with Mg, and n-GaN doped with Si were etched out by wet etching at 330° C. with a 3:1 mixture solution of sulfuric acid and phosphoric acid, it was shown that the speeds of etching were in the order of p-GaN<un-doped GaN<n-GaN, so their damage rate were in the same order, and the damage rate considerably increased as the temperature exceeded 300° C.

Judging from this result, in the case of forming the via hole by etching the sapphire base substrate together with the nitride semiconductor with the mixture etchant of sulfuric acid and phosphoric acid, it is preferable to use the un-doped GaN or Mg-doped GaN and to perform etching process at a temperature below 330° C. in order to increase the etching selectivity between the sapphire base substrate and the nitride semiconductor.

In some cases, it is possible to form an additional etch stop layer by partially forming a protection film of SiO₂ or SiNx at the area of the sapphire substrate 17 where the via hole is to be formed, before the buffer layer 16 is formed on the sapphire substrate 17. Particularly, the SiO₂ is efficient as an etch stopping layer since it is not etched out when the composition ratio of the sulfuric acid exceeds 50% in the mixed etchant of the sulfuric acid and the phosphoric acid.

FIG. 6 is graph for illustrating the etching speed of the sapphire and GaN in ICP/RIE dry etching.

As shown in FIG. 6, as the ICP and RIE powers increase, the etching speeds of the sapphire and the nitride series semiconductors increase, but the etching selectivity between the sapphire and nitride series semiconductors decreases. Furthermore, the etching speed of nitride series semiconductors is higher than that of the sapphire.

These results shows that when ICP/RIE is used as etching method, etch stopping at the buffer layer 16 of nitride series semiconductors is difficult such that it is required to utilize techniques such as an optical analysis technique or a residual gas analysis technique for stopping the etching process at the buffer layer 16. In spite of using these techniques, however, the success probability is likely to be low. But in the wet etching method it is possible to secure the process margin required for mass production by using the nitride series buffer layer 16 as the etch stop layer.

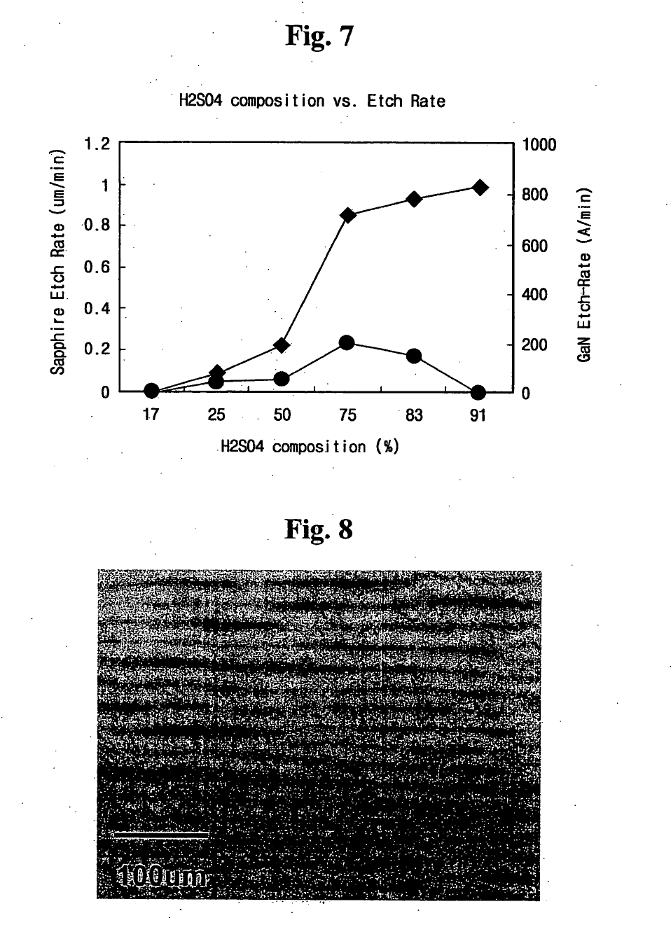

FIG. 7 is a graph for illustrating the etching speeds of the sapphire and GaN by means of the wet etching technique with the mixture etchant of sulfuric acid and phosphoric acid. In FIG. 7, squares are sapphire etch rate and circles are GaN etch rate.

As shown in FIG. 7, the etching selectivity rate of the sapphire to the nitride series semiconductor in the mixture etchant of sulfuric acid and phosphoric acid can exceed 50. This result shows that the buffer layer 16 can be efficiently utilized as the etch stopping layer of the sapphire substrate 17. It was proved by experiment that obtaining etching selectivity rate of over 20 is possible, even though the process temperature of etching is 100° C.

Particularly, the etching speed of the sapphire exceeds 1 um/min when etching temperature is over a specific value.

The proposed method of the present invention is superior to the conventional ones in consideration of the whole manufacturing costs, productivity, and process stability.

In the examination of the dependency of the sulfuric acid and phosphoric acid, mixture ratio of the etchant and the etching speeds of the sapphire and the nitride series semiconductor, the etching speed of the sapphire is shown to be much faster and the damage amount of the nitride series semiconductor is small when the sulfuric acid percentage exceeds 50%. Otherwise, if the sulfuric acid percentage increases to exceed 90%, the damage of the nitride series semiconductor is small enough but the sapphire etching speed become slower again.

If the percentage of sulfuric acid becomes below 50%, the sapphire etching speed becomes too slow, the damage of the nitride semiconductor increases, and the etching speed of the SiO2 become fast such that SiO2 can not work as the etching mask. Accordingly, it is required to use an etchant including sulfuric acid over 50% in order to secure stable process conditions by increasing the etching speed of the sapphire and the etching selectivity of the sapphire and nitride semiconductor.

However, only with the wet etching technique it is limited to make the vertical electrode-type light emitting diode stable.

As shown in FIG. 7, when the sapphire substrate 17 is etched by using an mixed etchant of the sulfuric acid and phosphoric acid, it is not easy to evenly etch out the buffer layer 16 to expose n-type contact layer 15 because the nitride series semiconductor is etched little or unevenly by the mixed etchant of the sulfuric acid and phosphoric acid.

Accordingly, it is preferred to efficiently utilize the dry etching technique such as ICP/RIE or RIE for evenly etching the un-doped nitride series semiconductor buffer layer 16 and stopping the etching process at the n-type contact layer 15 of the nitride series semiconductor. That is, by using both the wet etching and dry etching techniques as the method for manufacturing the vertical electrode-type nitride semiconductor light emitting diode by etching the sapphire substrate 17, it is possible to stably and evenly remove the sapphire substrate and evenly etch out the nitride series semiconductor buffer layer 16 so as to expose the n-type contact layer 15, thereby allowing the second electrode 19 to be stably formed.

FIG. 8 is a photograph showing the buffer layer after the sapphire substrate is removed by means of the wet etching technique.

As shown in FIG. 8, there is almost no breakage or damage of the thin film, which is caused by stress, and the etched surface is clean.

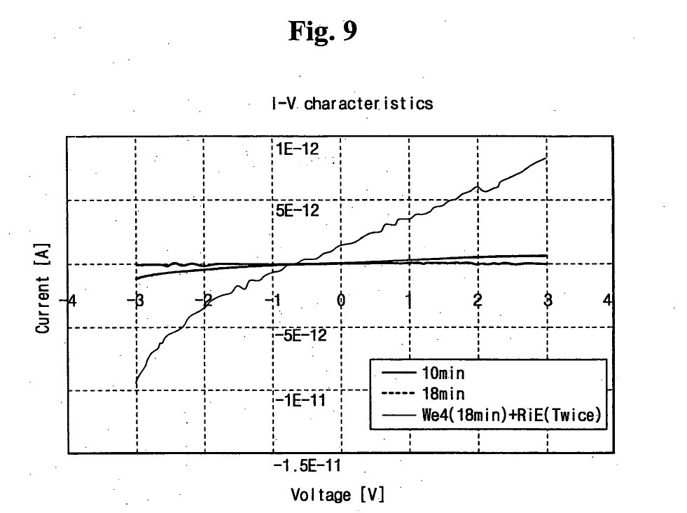

FIG. 9 is a graph showing the voltage-current characteristic curve of the nitride series semiconductor layer after the sapphire substrate is removed.

As shown in FIG. 9, it is shown that the current does not flow before the sapphire substrate 17 is removed, but it flows as much as a few pA with applying 1V after the sapphire substrate 17 is removed, and then abruptly increases to 40 pA after the nitride series semiconductor buffer layer 16 is removed by means of ICP/RIE or RIE. At this time, one of BCL₃, Cl₂, HBr, and Ar gases or a mixture gas including at least one among them is used as the etching gas for ICP/RIE or RIE.

Judging from this result, it is known that the n-type nitride series semiconductor contact layer 15 is exposed by efficiently etching the nitride series semiconductor buffer layer 16 and the sapphire substrate 17 by using both of the wet and dry etching techniques.

This voltage-current characteristic is a significant result for that the etching process can be efficiently monitored by measuring the electric characteristic of the exposed surface using a probe station at each process.

The thickness of the sapphire after the etching process can be inspected with an optical method. That is, if a light is projected to a medium, it partially reflects on the surface of the medium and partially transmits the medium. The reflection and penetration of the light is dependent on a refraction index of the medium and the wavelength of the light such that it is possible to measure the thickness of the sapphire by analyzing the interference spectrum of the reflected light and the transmitted light. An example of a tool for this is the ellisometer.

Next, the second ohmic layer 18 and the second electrode 19 are formed by depositing a conductive material, which can form the ohmic contact, such a mixture including at least one of Ti, Al, Rh, Pt, Ta, Ni, Cr, Au, and Ag, and etching out by means of the photo-etch technique.

After depositing the second electrode 19, the ohmic contact is formed by performing heat treatment in a furnace under a nitrogen atmosphere at the temperature of 300° C.˜700° C. (preferably 400° C.˜600° C.) between the second electrode 19 and the second ohmic layer 18 so as to decrease the contact resistance between the semiconductor and the metal.

It is preferred that the contact resistance between the metal and semiconductor is below 1×10⁻¹ Ωcm² in order to lower the operation voltage of the light emitting diode.

The first electrode and the second electrode can be formed after the formation of the via hole. In this case, the process is carried out in such a manner of depositing an SOG or SiO2 protection layer on the nitride semiconductor surface to a thickness of 1 um, polishing the sapphire in the range of 10 um˜30 um, cleaning the surface of the sapphire by irradiating light or wet etching with one or a mixture etchant including at least one of acetone, hydrochloric acid (HCl), nitric acid (HNO3), potassium hydroxide (KOH), sodium hydroxide (NaOH), sulfuric acid (H2SO4), phosphoric acid (H3PO4), and Aluetch (4H3PO4+4CH3COOH+HNO3+H2O). After cleaning the sapphire surface, the via hole is formed by depositing and patterning SiO2 on the surface of the sapphire in the thickness of 1 um and performing the wet etching with the etchant, which is one or a mixture containing at least one of hydrochloric acid(HCl), nitric acid(HNO₃), potassium hydroxide(KOH), sodium hydroxide (NaOH), sulfuric acid(H2SO4), phosphoric acid (H3PO4), and Aluetch (4H3PO4+4CH3COOH+HNO3+H₂O). After forming the via hole, the buffer layer is etched out by means of RIE or ICP/RIE dry etching technique and the second ohmic layer 18 and the second electrode 19 are formed. After removing the oxide film of SiO2 of the nitride semiconductor surface, the first ohmic electrode 11 and the first electrode 12 is formed with a metal alloy constituted at least one of Ti, Ni, Pt, and Au, and then cleaving is performed to separate each chips.

In the present invention, since the sapphire substrate is removed by means of polishing and the dry and wet etching techniques, it is possible to enhance productivity, and particularly it is possible to prevent the epitaxial layers from getting thermal damage caused when using the laser lift off technique. Also, by utilizing the etching selectivity between the sapphire substrate and the nitride semiconductor, it is possible to improve the reproducibility of the process and to facilitate mass production with a normalized process.

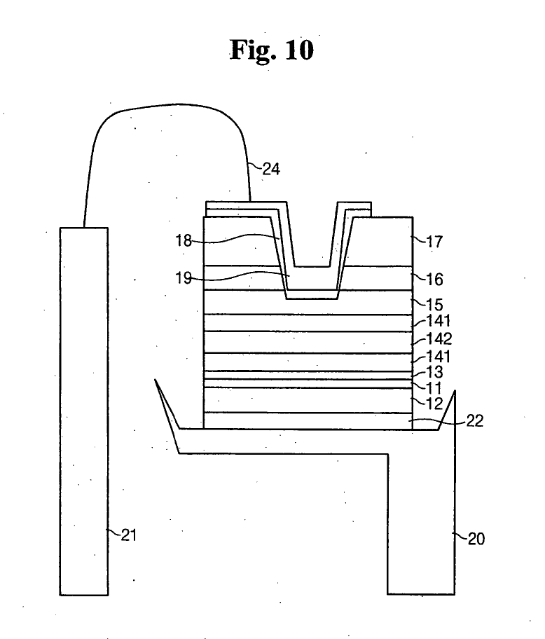

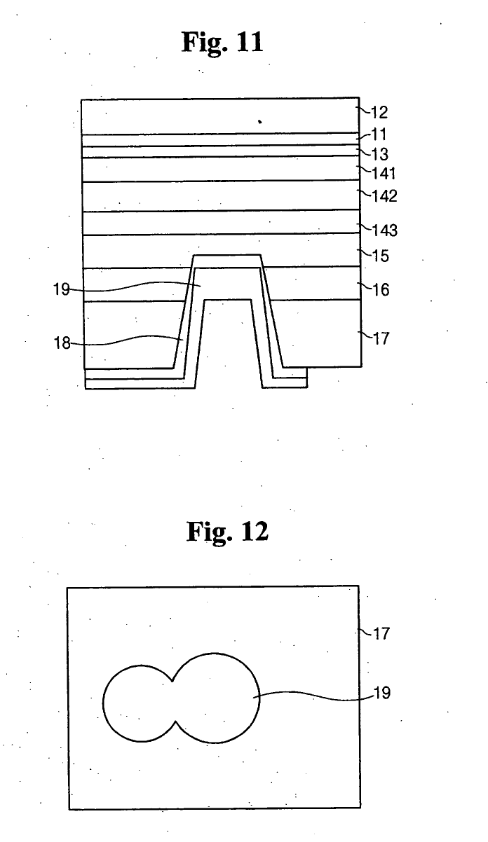

FIG. 10 is a sectional view illustrating a vertical electrode structure-type light emitting diode according to a third embodiment of the present invention, FIG. 11 is a sectional view illustrating a vertical electrode-type light emitting diode according to the third embodiment of the present invention, and FIG. 12 is a plane view of the light emitting diode according to the third embodiment of the present invention, shown on the sapphire substrate.

In the third embodiment of the present invention, an electrode pad is formed on the sapphire substrate 17 by expanding the second ohmic layer 18 and the second electrode 19 outward the via hole in order to prevent the nitride series semiconductor layers 15, 141, 142, 143, and 11 from being damaged due to the pressure applied thereto when the second electrode 19 and the wire 24 are bonded. The shape and position of the second electrode 19 pad can be variously modified and it is possible to adopt the shape of FIG. 4.

In the meantime, the light is concentrated in the normal direction of the sapphire substrate 16 by the prominences and depressions on the surface of the sapphire substrate 17. Here, he unit length of prominence and depression are preferably greater than ¼n (“n” is refraction index. For the depression, “n” is the refraction index of sapphire and for the prominence, “n” is the refraction index of air) so as the prominence and depression to have photonic crystal characteristics.

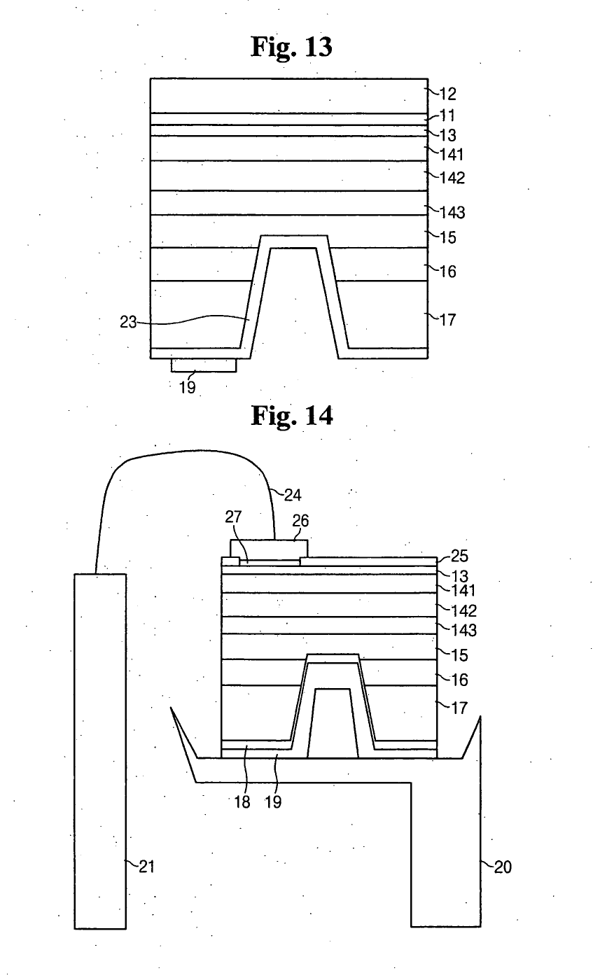

FIG. 13 is a sectional view illustrating a light emitting diode chip having the vertical electrode structure according to a fourth embodiment of the present invention, in which the light is extracted from the base substrate.

In the fourth embodiment, on behalf of the second ohmic layer, a transparent conductive substance such as ITO, ZrB, ZnO, InO, SnO, and the like is coated on the surface of sapphire substrate 17 and the second electrode 19 is narrowly formed only around the via hole. This is for broadening the light path by reducing the size of the opaque second electrode 19. In order to secure the space for bonding the wire, the ohmic layer 23 is coated on the surface of the sapphire substrate 17 at an area broader than a predetermined area.

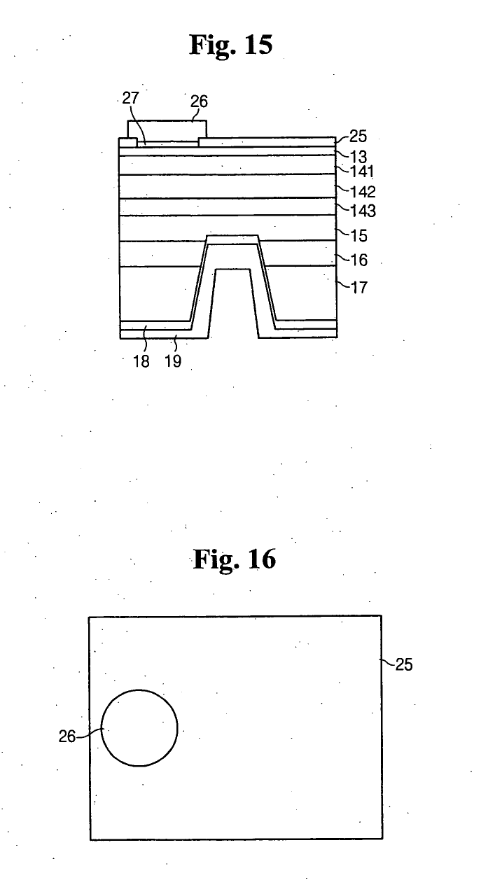

FIG. 14 is a sectional view illustrating a light emitting diode having a vertical electrode structure according to a fifth embodiment of the present invention, FIG. 15 is a sectional view illustrating a light emitting diode chip having the vertical electrode structure according to the fifth embodiment of the present invention, and FIG. 16 is a top plan view illustrating the light emitting diode chip shown on the first electrode according to the fifth embodiment of the present invention.

The light emitting diode chip according to the fifth embodiment of the present invention has the structure as following.

The first electrode 25 can be formed so as to be a transparent by thinly depositing a metal containing at least one among Ni, Ti, Au, Pd, Rh, Pt, Al, Cr, and Ag, and can be thermally treated in an oxide atmosphere.

In case of forming the first electrode 25 with Ni/Au, Ti/Ni/Au, Pt, Ni/Pt, or Ni/Au/Ni, the first electrode 25 is preferably deposited over the entire surface and thermally treated at a temperature over 400° C. to be an ohmic electrode having a light permeable and conductive characteristic. Also, the first electrode 25 can be formed with the transparent conductive material such as Inₓ(Ga_{y}Al_{1-y})N doped by Si, ITO, ZrB, ZnO, InO, SnO, or the like.

In some cases, the sapphire substrate 17 can be entirely removed when the first electrode 25 can be a support of the chip. Particularly, in case of using Inₓ(Ga_{y}Al_{1-y})N as the first electrode, the Inₓ(Ga_{y}Al_{1-y})N layer is formed at the thickness of 0.1 um-500 um (preferably, over 10 um) by means of hydride vapor phase epitaxy (HVPE) so as to be a support layer in place of the sapphire substrate 17. In this case the sapphire substrate 17 may be thinly remained.

On the first electrode 25, a first electrode pad 26 is formed for bonding a wire 24. Here, the first electrode 25 has an opening at the position of the first electrode pad 26 and a dielectric film 27, such as SiNx, SiO2, and ZrO, is coated on the inside of the opening. That is, the dielectric film 27 prevents the first electrode pad 26 from direct contacting with the p-type contact layer 13. This is for preventing current concentration just below the first electrode pad 26 and providing a cushion for wire bonding.

In the meantime, the first electrode 25 positioned right below the first electrode pad 26 is formed with the metal such as Al, Cr, and Ti having the Schottky characteristic so as to prevent the current from concentrating right below the first electrode pad 26.

Also, the first electrode pad 26 is preferably formed at the area which is not overlapped with the via hole for preventing the nitride series semiconductor thin layer from being damaged when the wire 24 is bonded.

The first ohmic reflection layer 11 previously described in the first to fourth embodiments is not adopted, since the first electrode 25 formed with the transparent or pemialbe conductor forms an ohmic contact with the p-type contact layer 13.

On the bottom surface of the sapphire substrate 17, the second ohmic and light reflection layer 18 and the second electrode 19 are formed on the entire surface of the sapphire substrate 17 and inner surface of the via hole. The second ohmic and light reflection layer 18 and the second electrode 19 may be integrally formed as a single layer or may be formed to have multi layers structure over three layers. The second ohmic and light reflection layer 18 and the second electrode 19 can be metallic structure of Al, Ti/Al, Ti/Al/Au, Rh/Au, Pd/Au, Al/Pt/Au, Ni/Ti/Au, or the like.

The first electrode 19 can be formed thickly for improving heat release effect when the chip is mounted on a lead frame or a printed circuit board (PCB), and preferably formed by plating Au, Cu, Ni, Al, Pt, or the like. The plating process can be performed by means of an electroplating or an electroless plating.

The method for manufacturing the light emitting diode chip is similar to that of the first embodiment except that the first electrode pad 26 is formed at the final stage after forming the first electrode 25 with the transparent conductive material and etching the first electrode 25 by the photo-etching technique so as to expose a part of the p-type contact layer 13.

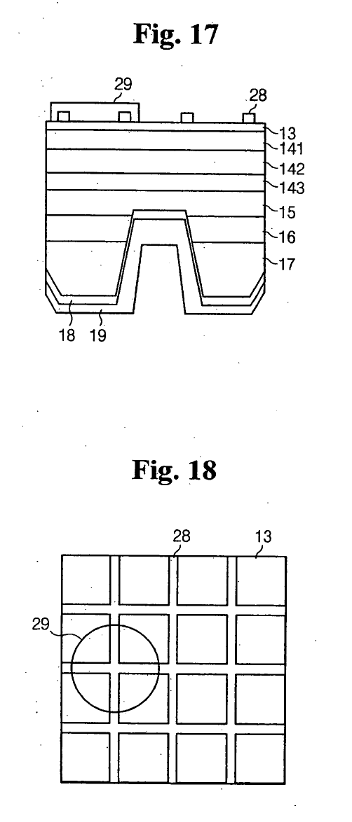

FIG. 17 is a sectional view illustrating a light emitting diode chip having a vertical electrode structure according to a sixth embodiment of the present invention and FIG. 18 is a top plan view illustrating the light emitting diode chip of the vertical electrode structure according to the sixth embodiment of the present invention, shown in a direction of the first electrode.

The sixth embodiment is characterized, in comparison with the fifth embodiment, in that the first electrode 28 is formed with an ohmic metal on the p-type contact layer 18 in a lattice structure so as to enable the light to pass, the bottom edges of the sapphire substrate 17 are chamfered by a etching process, and the first electrode pad 29 is formed of the first electrode 28.

In this structure, since the bottom edges of the sapphire substrate 17 is chamfered, the reflection and ohmic layer 18 is formed along the chamfered surface.

This structure can efficiently reflect the incoming light directed toward the bottom surface so as to direct in a direction of the first electrode 28. This chamfered structure helps the light to transmit the second electrode 19 and the ohmic layer 18 and to be emitted in side direction of the chip. The emitted light is reflected by the lead frame so as to be emitted upward.

Here, the chamfers are formed as the boundaries between the individual chips during the etching process for forming the via hole. Here, it is required, at the boundaries of chips, that the sapphire substrate 17 does not separated in unit of chip during the etching process by making the opening of the etching mask narrower than the area on which the via hole is form.

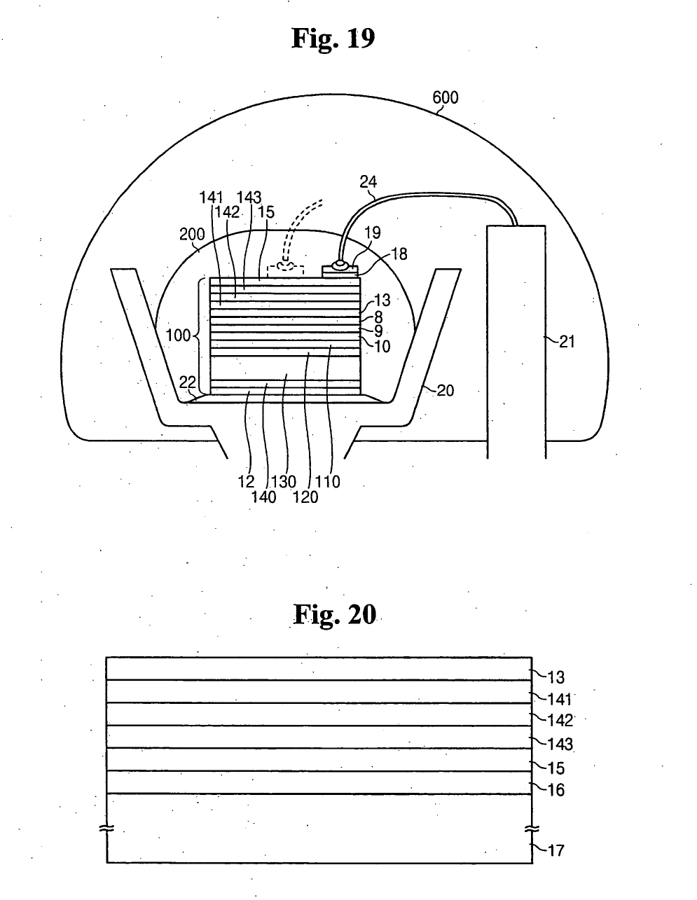

FIG. 19 is a sectional view illustrating a light emitting diode having a vertical electrode structure according to a seventh embodiment of the present invention.

The light emitting diode according to the seventh embodiment of the present invention includes a lead frame 20, a chip 100 bonded on a lead frame 20, and a wire 24 for connecting an electrode of the chip 100 to a lead frame 21. The chip 100 is covered by a fluorescent material 200 and the lead frame 20 and 21 are covered by a resin 600. The fluorescent material 200 may not be equipped in case of using the light as the chip 100 emits.

The chip 100 includes of a first electrode 12, a first receptor contact layer 140, a receptor substrate 130, a second receptor contact layer 120, a receptor adhesion metal layer 110, an epitaxy adhesion metal layer 10, a light reflection layer 9, a conductive transparent layer 8, a p-type contact layer 13, p-type clad layer 141, a light emitting layer 142, a n-type clad layer 143, and n-type contact layer 15, an ohmic layer 18, and a second electrode 19 being formed on the n-type contact layer 15 which are sequentially piled up.

Here, the receptor substrate 130 plays a role of a support of the light emitting diode and a passage of current. The receptor substrate 130 can be any one of semiconductor substrate such as Si, GaAs, GaP, InP, and InAs; a conductive oxide substrate such ITO, ZrB, and ZnO; and a metal film or metal substrate such as Cu, W, CuW, Au, Ag, Mo, and Ta. It is required that the receptor substrate has the conductivity since it should be a passage of current as well as an element of the light emitting diode.

The receptor adhesion metal layer 110 and the epitaxy adhesion metal layer 10 is formed With an eutectic metal containing at least one of Ti, Sn, In, Pt, Ni, Pd, Ag, Au, Rh, and Ag. The two metal layers 110 and 10 are bonded by thermal compression such that the receptor substrate 130 and epitaxial layer are adhered to each other. Here, the adhesion metal layer 110 and 10 can be replaced with an epoxy film having conductivity.

Since the nitride semiconductor wafer to which the receptor substrate is adhered by thermal compression is dipped into the etchant of sulfuric acid and phosphoric acid, the eutectic metal and metal substrate or the metal film are preferably made of materials which are not damaged by the mixture of the sulfuric acid and phosphoric acid. Since the Pt and Au is not effected by the mixture solution of sulfuric acid and phosphoric acid, it is preferred that the metal structure containing the Pt and Au, preferably Tt/Au, Ti/Au, Ge/Au, Rh/Pt/Au, and the like.

Also, the buffer layer 16, n-type contact layer 15, n-type clad layer 143, light emitting layer 142, p-type clad layer 141, and p-type contact layer 13 are formed with Inₓ(Ga_{y}Al_{1-y})N (1≧x≧0, 1≧y≧0), and the light reflection layer 9 is formed as a single layer or multiple layers containing at least one among Ni, Cr, Al, Ag, Au, Cu, Rh, Pd, and Pt so as to enhance the light reflection characteristic. It is possible to exclude the light reflection layer 9, however it is preferred to form the light reflection layer 9 to enhance the light extraction efficiency. Here, the n-type contact layer 15 is doped with Si dopants of which concentration is greater than 10¹⁸atoms/cm³, and the p-type contact layer 13 is doped with Mg dopant of which concentration is greater than 10¹⁸ atoms/cm³.

The first electrode 12 is formed with a metal alloy containing at least one of Ni, Cr, Rh, Pd, Au, Ti, Pt, Ta, and Al, and the second electrode 19 is formed with a metal alloy containing at least one of Ti, Al, Rh, Pt, Ta, Ni, Cr, and Au.

Here, the first electrode 12 and the second electrode 19 can be formed with a transparent conductive material such as ITO, ZnO, InO, SnO, and Inₓ(Ga_{y}Al_{1-y})N (1≧x≧0, 1≧y≧0), as a single layer or multiple layers containing at least one of Al, Ti/Al, Ti/Au, Rh/Au, Pd/Au, and Al/Pt/Au.

The ohmic layer 18 plays a role of reducing a ohmic contact resistance of the second electrode 19 and the n-type contact layer 15, and the ohmic layer 18 can be formed with the transparent conductive material such as ITO, ZrB, ZnO, InO, and SnO in order to facilitate the current distribution and increase the light extraction efficiency.

The second receptor contact layer 120 is formed with any of Ni, Au, Ti, Pd, Rh, Pt, Al, Cr, and Ag, or a mixture of at least two of them as thin film so as to be transparent as well as conductive. Particularly, in case of using Pt for the second receptor contact layer 120, it can be formed in the thickness less than 200 Å by means of thermal treatment at the temperature about 300˜500□.

In the chip 100, the surface of the first electrode 12 is applied to the lead frame 20 with the conductive paste 22 and the second electrode 19 is connected to the lead frame 21 through wire 24. In the above structured light emitting diode, the second electrode 19 and the first electrode 12 are separately formed on the top and bottom sides, respectively, of the chip such that it is possible to reduce the size of the chip. As a result, the productivity per wafer increases. Also, since the receptor substrate 130, as chip structure, has superior thermal and electric conductivities, it is possible to efficiently discharge the heat and static electricity. Furthermore, since the current evenly flows through the whole surface of the chip, it is possible to operate at high current. Accordingly, it is possible to obtain high light output with unit device. In case of using a metal as an auxiliary substrate, the metal substrate can be formed by applying with the thermal compression or thick plating. As for the formation of the metal film, it is preferred to use the depositing, electric plating, or electroless plating.

Now, a method for manufacturing the above-structured light emitting diode will be described.

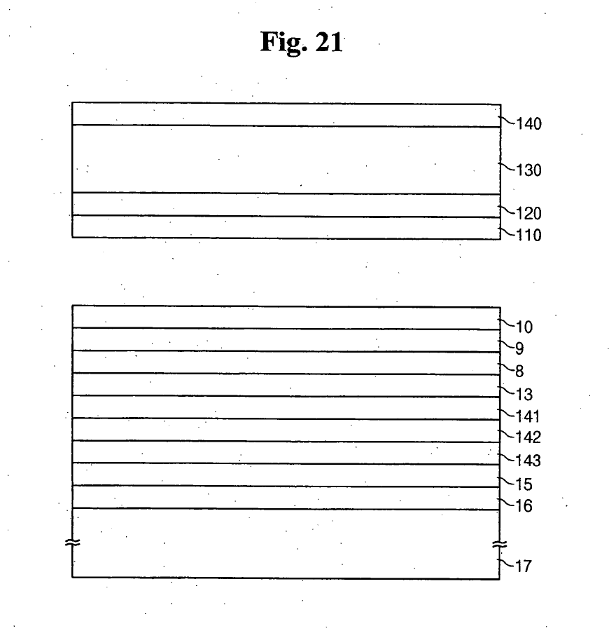

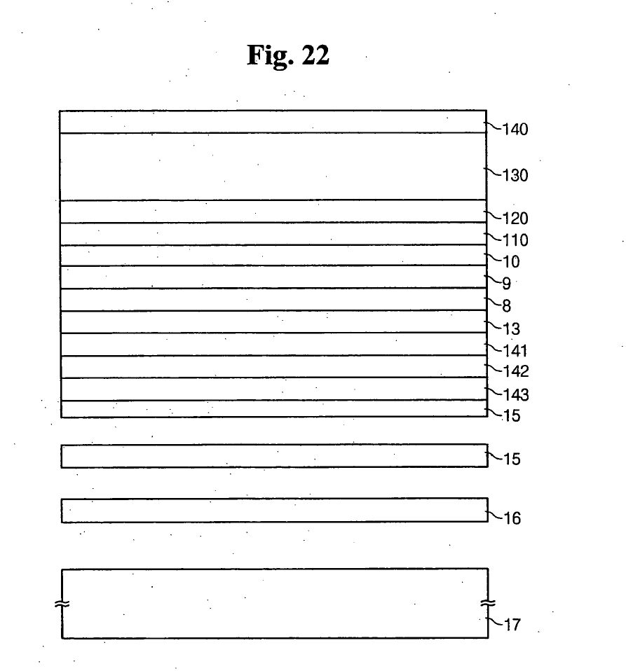

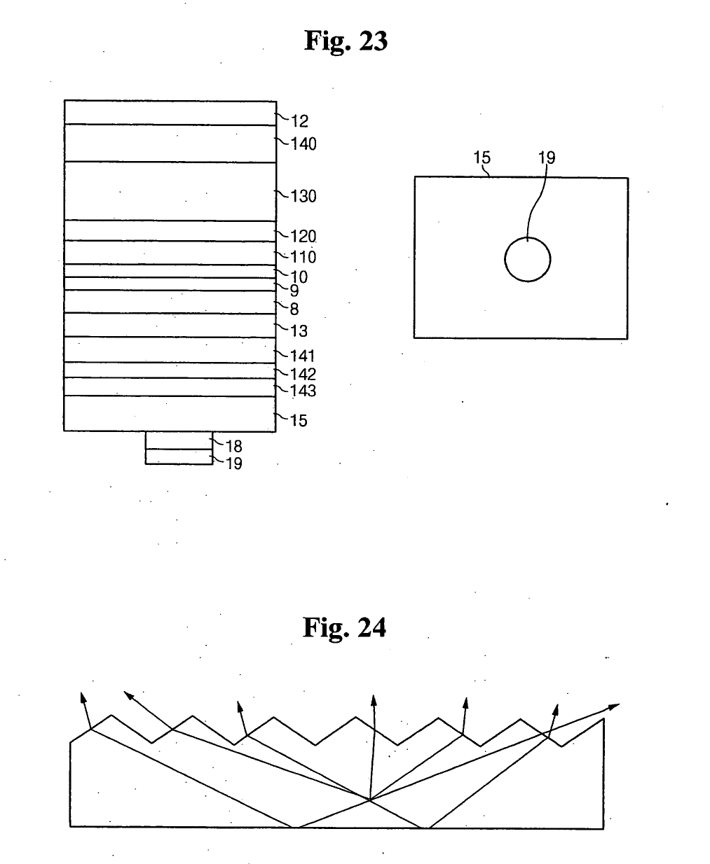

FIG. 20 is a sectional view for illustrating a middle stage of manufacturing the light emitting diode according to the seventh embodiment of the present invention. FIG. 21 is a sectional view showing the next stage of FIG. 20 and illustrating how the electrode substrate is attached to the base substrate on which epitaxial layers and a contact layer are formed. FIG. 22 is a sectional view showing the next stage of FIG. 21 and illustrating how the base substrate is removed. FIG. 23 is a sectional view showing the next stage of FIG. 22 and illustrating how the first and second electrodes are formed.

As shown in FIG. 20,) the buffer layer, n-type contact layer 15, n-type clad layer 143, light emitting layer 142, p-type clad layer 141, and p-type contact layer 13 are sequentially deposited on the sapphire (Al₂O₃) by using at least one of the metal organic chemical vapor deposition, liquid phase epitaxy, molecular beam epitaxy, hydride vapor phase epitaxy, and metal organic vapor phase epitaxy.

Next, as shown in FIG. 21, the ohmic electrode or the conductive transparent electrode 8 and the light reflection layer 9 are formed on the p-type contact layer 13, and the epitaxy contact metal layer 10 is formed on the light reflection layer 9. Here, the depositions of the light reflection layer 9 and the ohmic electrode or conductive transparent electrode 8 is formed by means of an electron beam (E-beam), a thermal evaporation, and a sputtering techniques.

At this stage, in order to minimize the stress applied to the nitride series semiconductor epitaxial layer after removing the sapphire substrate 17, the epitaxial layer may be etched out with a predetermined distance in x- and y-directions by means of mesa etching. Here, the mesa etching is carried out by means of dry etching technique such as reactive ion etching (RIE) and inductive coupled plasma/reactive ion etching (ICE/RIE) and it is preferred that the nitride series semiconductor epitaxial layer is almost entirely removed.

Also, the first receptor contact layer 140 is formed on the upper surface of the receptor substrate 130 made of semiconductor or metal. The second receptor contact layer 120 and the receptor adhesive metal layer 110 are formed on the bottom surface of the receptor substrate 130.

Next, while contacting the epitaxial adhesion metal layer 10 and the receptor adhesion metal layer 110 with each other, the two adhesion metal layers 10 and 110 are fused and adhered by applying the pressure of 1˜6 MPa at the temperatures from 200 to 600° C. for 1 minute to 1 hour.

Here, it is preferred that process is carried out at the temperature of 320° C. for about 30 minutes, since the epitaxial layer 15, 143, 142, 141, and 13 and the receptor substrate 130 may be damaged by high temperature and by high pressure.

Also, the thermal compression process is carried out in a vacuum or a gaseous atmosphere of Ar, He, Kr, Xe, and Rn, or N2, halogen, and air (including O2) so as to overcome the energy gap between the metal and semiconductor by the contact layer.

At this time, the eutectic metal is preferably formed in such multiple layers or an alloy containing Pt or Au so as not to be damaged by the mixture solution of the sulfuric acid and phosphoric acid.

In the meantime, in stead of the adhesion layers 10 and 110, the receptor substrate can be attached on the epitaxial layer by using such a conductive epoxy film.

Also, the receptor substrate is formed with the metal substrate or metal film. In case of using the metal substrate as the receptor substrate, the metal substrate is applied by thermal compression, and in case of forming the metal film as the receptor substrate it is formed by depositing and thermal treating the ohmic contact and Pt/Au which can act as a seed material on the first electrode layer and then carrying out plating Au at the thickness from 0.1 um to 100 um.

Next, as shown in FIG. 22, the sapphire substrate 17 is removed by using at least one of machinery polishing, wet etching, and dry etching.

Here, the buffer layer 16 and a portion of n-type contact layer 15 are removed together with the sapphire substrate 17.

Since the buffer layer 16 absorbs a light having wave length shorter than 370 nm, when a light emitting diode emitting light having wavelength shorter than 370 nm is manufactured, the buffer layer 16 should be removed. However, when a light emitting diode emitting light having wavelength over 370 nm is manufactured, the buffer layer 16 may not be removed.

Also, In order to reduce the contact resistance, a portion of the n-type contact layer 15 is preferably removed at areas in which the film quality is bad.

Now, how to remove the sapphire substrate 17, buffer layer 16, and part of the contact layer 15 after the receptor substrate being deposited will be described in detail.

After depositing the protection layer such as the spin on glass (SOG), SiNx, and SiO₂ at the thickness from 1 um to 2 um on the receptor substrate for preventing the receptor substrate from being etched out or damaged during the wet etching, the sapphire substrate 17 is grinded and then the grinded surface is polished to be mirror like surface.

Here, lapping the sapphire substrate 17 is carried out by means of the chemical mechanical polishing (CMP), the ICP/RIE dry etching, the machinery polishing using the alumina (Al₂O₃) power or hydrochloric acid (HCl), or the wet etching with an etchant containing one or more of sulfuric acid(H₂SO₄), phosphoric acid(H₃PO₄), nitric acid(HNO₃), potassium hydroxide(KOH), sodium hydroxide(NaOH), and Aluetch (4H₃PO₄+4CH₃COOH+HNO₃+H₂O).

At this time, the thinner the thickness of the sapphire base substrate 17 is the better, however, it is preferred that the thickness is at the range from 5 um to 300 um (preferably 20 um˜150 um) since the nitride semiconductor thin layer can be damaged if thickness of the sapphire base substrate 17 is too thin.

Also, the roughness of the surface of the lapped sapphire substrate should be less than 10 um. This is because the roughness of the sapphire substrate 17 is reflected to the n-type contact layer 2 while etching the sapphire base substrate 17 and the buffer layer 16 such that the layered structure of the light emitting diode can be damaged or the uneven thickness causes an uneven quality of the light emitting diode, resulting in reduction of the yield late.

After the lapping and polishing, the sapphire base substrate 17 is etched out by means of one or more of wet or dry etching techniques. The sapphire can be etched by dry or wet etching as previous etching technique. As the dry etching, ICP/RIE or RIE is preferred, and as for the wet etching, it is preferred to use an etchant containing one or more among hydrochloric acid(HCl), sulfuric acid(H₂SO₄), phosphoric acid(H₃PO₄), nitric acid(HNO₃), potassium hydroxide(KOH), sodium hydroxide(NaOH) and Aluetch (4H₃PO₄+4CH₃COOH+HNO₃+H₂O). As for the dry etching, in order to rapidly etch out the sapphire base substrate, it is required to increase the ICP and RIE powers. However, it is carefully considered to increase the ICP and RIE powers because the high ICP and RIE powers may damage the nitride series semiconductor epitaxial layer.

Here, the wet etch of the sapphire base substrate 17 is carried out as following.

After measuring the etching speed of the sapphire substrate 17 by trying to etch a test sapphire substrate with the etchant containing one or more among the hydrochloric acid(HCl), sulfuric acid(H₂SO₄), phosphoric acid(H₃PO₄), nitric acid(HNO₃), potassium hydroxide(KOH), sodium hydroxide(NaOH), and Aluetch (4H₃PO₄+4CH₃COOH+HNO₃+H₂O) as increasing the temperature of the etchant over 100□ so as to measure, the work piece is dipped during the time in which a sapphire having the thickness corresponding to 110%˜120% of the sapphire base substrate 17 can be etched out.

The reason why taking the etching time to etch a sapphire having the thickness of 110%˜120% thickness is minimize the sapphire remainders after the etching process due to the irregular thickness of the sapphire substrate 17.

Here, the etching speed of the buffer layer 16 is slower as much as 1/50 than that of the sapphire substrate.

The etching selectivity rate of the buffer layer 16 to the sapphire base substrate 17 is over 50.

Accordingly, even though the etching progresses over the time required to remove the sapphire substrate 17, other layers under the buffer layer 16 is not damaged due to the buffer layer is etched out much slowly.

In the meantime, it is preferred to maintain the temperature of the etchant over 100□ for shortening the etching time. In order to maintain the temperature of the etchant over 100□, the etchant is heated by a direct heating method in which the etchant is positioned on a heater or directly contacts the heater or by an indirect heating method using the optical absorption with the halogen lamp.

Also, in order to maintain the temperature of the etchant over the boiling point, pressure may be applied. In case of using the wet etching, the sapphire base substrate 17 is etched out as much as 22.16 um for 20 minutes such that the etching speed is 1.1 um/min.

This etching speed is worthy of close attention and does not cause problems in consideration of mass production. The wet etching technique is advantageous in view of mass production in comparison with other techniques because a plurality of wafer can be wet etched at a time by one wet etching equipment.

Here, the sapphire substrate 17 can be partially removed with pattered SiO2 mask or entirely removed without the patterned SiO2 mask so as to expose the nitride semiconductor layer.

In the case of adopting the present invention to mass production, it is important to secure the process conditions with which the etching selectivity ratio of the sapphire substrate 17 to the nitride series semiconductor is large enough. It is efficient way for mass production to use the nitride series semiconductor as an etch stopping layer. The nitride semiconductor layer made of Inₓ(Ga_{y}Al_{1-y})N series materials (1≧x≧0, 1≧y≧0) can be used as an etch stopping layer. It is preferable for etch stopping to increase the composition ratio of Al and to use p-Inₓ(Ga_{y}Al_{1-y})N series materials doped with Mg in the concentration of 1×10¹⁷ cm⁻³.

When un-doped GaN, p-GaN doped with Mg, and n-GaN doped with Si were etched out by wet etching at 330° C. with a 3:1 mixture solution of sulfuric acid and phosphoric acid, it was shown that the speeds of etching were in the order of p-GaN<un-doped GaN<n-GaN, so their damage rate were in the same order, and the damage rate considerably increased as the temperature exceeded 300° C.

Judging from this result, in the case of forming the via hole by etching the sapphire base substrate together with the nitride semiconductor with the mixture etchant of sulfuric acid and phosphoric acid, it is preferable to use the un-doped GaN or Mg-doped GaN and to perform etching process at a temperature below 330° C. in order to increase the etching selectivity between the sapphire base substrate and the nitride semiconductor.

Also, it is possible to form a protection layer by depositing any of the spin-on-glass (SOG), SiNx, and SiO2 in order to prevent the receptor substrate 130 from being damaged or by adding one or more among Au, Pt, Fh, and Pd that are not damaged by the etchant.

The metal such as Pt and Au and thin film such as SOG, SiNx, and SiO2 which are not etched by the etchant containing one or more among the hydrochloric acid(HCl), sulfuric acid(H₂SO₄), phosphoric acid(H₃PO₄), nitric acid(HNO₃), potassium hydroxide(KOH), sodium hydroxide(NaOH), and Aluetch (4H₃PO₄+4CH₃COOH+HNO₃+H₂O), and are robust against the dry etching such as ICP/RIE may be formed on the receptor substrate 130 to protect the receptor substrate 130.

As shown in FIG. 23, after etching out the buffer layer 16 with the ICP/RIE or RIE dry etching, the second ohmic layer 18 and the second electrode 19 are sequentially formed. The second ohmic layer 18 is formed by depositing and lifting off a conductive transparent electrode such as ITO, InSnO, and ZnO or one or an alloy of Ti, Al, Rh, Pt, Ta, Ni, Cr, and Au which can form an ohmic contact with the n-type contact layer 15 and then carrying out a thermal treatment at the temperatures from 300□ to 700□ in an atmosphere containing nitride and oxide.

Preferably, the structures of the second ohmic layer 18 and the second electrode 19 are formed with Ti/Al, Ti/Ni/Au, Ni/Ti/Au, Ni/Au, Ti/Cr/Au, and Cr/Ni/Au, and in case of entirely depositing the second ohmic electrode, it is possible to thinly deposit the second ohmic layer so as to enhancing the light penetration. Also, the first electrode 12 is formed on the first receptor contact layer 140.

Sequentially, the light emitting diode substrate is separated into chips by means of dicing/sawing or scribing/braking.

Next, the chip is mounted on the lead frame 20 using the conductive paste 22 and the second electrode 19 is connected to the lead frame 21 by bonding the wire.

Sequentially, the chip is packaged with the epoxy after doping the fluorescent substance 200. As described above, since the sapphire substrate 17 is removed using the back side lapping and the dry or wet etching, the productivity is improve, and it is possible to prevent the epitaxial layers from getting thermal damage caused when using the laser lift off technique.

Also, as shown in FIG. 24, it is possible to increase the light extraction efficiency as well as to concentrate the light by patterning the sapphire substrate into various shape using the wet etching such that fine prominences and depressions are formed on the surface of the n-type contact layer 15.

FIG. 24 is a drawing illustrating a sectional profile of the n-type contact layer 15 and the light extracting effect after removing the sapphire substrate by means of the back side lapping and etching techniques.

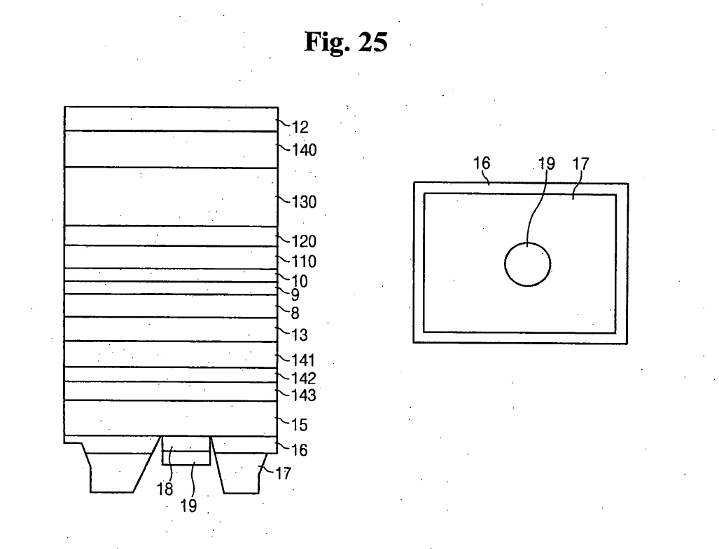

FIG. 25 is a sectional view illustrating the light emitting diode having a vertical electrode structure according to an eighth embodiment of the present invention.

As shown in FIG. 25, a buffer layer 16, a n-type contact layer 15, a n-type clad layer 143, a light emitting layer 142, a p-type clad layer 141, and a p-type contact layer 13 are sequentially deposited on the sapphire substrate 17, and a first ohmic contact layer 8, contact metal layer 9, and epitaxy adhesion metal 10 having light reflection characteristic are sequentially deposited on the the p-type contact layer 13. A receptor adhesion layer 110, a receptor ohmic contact layer 120, a receptor substrate 130, a first receptor contact layer 140, and a first electrode 12 are sequentially formed on the epitaxy adhesion metal 10.

A via hole is formed through the sapphire substrate 17 and the buffer layer 16. The n-type contact layer 15 is exposed through the via hole and the second reflection and ohmic layer 18 and the second electrode 19 are connected to the n-type contact layer 15 through the via hole.

The eighth embodiment of the present invention has a structure formed by bonding the receptor substrate 130 and the nitride semiconductor with each other using the eutectic metals 10 and 110 using the thermal compression technique, forming the via hole penetrating the sapphire substrate 17 and the buffer layer 16, and forming the second ohmic layer 18 and the second electrode 19 contacting the n-type contact layer 15 through the via hole.

It is preferred to form the epitaxial light reflection layer 9 between the adhesion metal layer 110 and the p-type contact layer 13 and the first ohmic contact layer 8 can be replaced with the conductive transparent electrode for enhancing the light reflection characteristic.

The present invention can be adopted for all kinds of nitride series semiconductor of Inₓ(Ga_{y}Al_{1-y})N series grown on the sapphire base substrate as well as the blue nitride series light emitting device having the wavelength of 470 nm, and particularly in case of manufacturing the nitride series light emitting device the Inₓ(Ga_{y}Al_{1-y})N (1≧x≧0, 1≧y≧0) layer used as the buffer layer can be removed, such that the present invention is useful for the device emitting light at around or below 365 nm which is the band gap wavelength of the GaN.

The present invention is a core technology in the LED illumination field, which is capable of enhancing the reliability and brightness and enabling to manufacture the high brightness/high performance nitride semiconductor light emitting device by reducing the size of the chip so as to improve the productivity and performance of the device.

The present invention has been described with the embodiments depicted in the accompanying drawings, but merely exemplary, various modifications are possible and be understood by those skilled in the art. Thus, the protection range of the present invention is restricted by the claims attached herewith.

As described above, in the present invention the two electrodes are separately formed on the respective top and bottom surfaces such that the chip size reduces, resulting in increase the chip productivity per wafer.

Also, since the nitride series semiconductor light emitting diode of the present invention has a structure in which the second electrode is formed with metal in the via hole, the second electrode enables to efficiently discharge the heat and static electricity.

Also, since the current can regularly flow over the entire surface of the chip, the chip can operate with the high current. Thus, it is possible to obtain the high optical output with a single device.

Furthermore, in the present invention, since the sapphire substrate is removed using the double side lapping and the dry or wet etching techniques, the productivity improved, and particularly in case of using the laser lift of technique it is possible to prevent the epitaxial layer from being thermal damaged. Also, using the etching selectivity between the sapphire substrate and nitride semiconductor, the process reproducibility can be improved and facilitate the mass production with the normalize process.

1. A light emitting diode comprising:
a base substrate having a via hole;
a first conductive contact layer formed on the base substrate;
an active layer formed on the first conductive contact layer;
a second conductive contact layer formed on the active layer;
a first electrode formed on the second conductive contact layer; and
a second electrode connected to the first conductive contact layer through the via hole.

2. The light emitting diode of claim 1, further comprising:
a buffer layer formed between the base substrate and the first conductive contact layer and having a via hole partially overlapping the via hole of the base substrate; and
a ohmic and reflection layer formed between the second electrode pad and the first conductive contact layer.

3. The light emitting diode of claim 2, wherein the second electrode expands outside of the via hole so as to form a pad on the base substrate.

4. The light emitting diode of claim 2, wherein the first electrode is formed as a single layer or multiple layers containing at least one among Ni, Cr, Rh, Pd, Au, Ti, Pt, Au, and Ta; and the second electrode is formed as a single layer or multiple layers containing at least one among Ti, Al, Rh, Pt, Ta, Ni, Cr, Au, and Ag.

5. The light emitting diode of claim 1, wherein the first conductive contact layer, the active layer, the second conductive contact layer, and the buffer layer include Inₓ(Ga_{y}Al_{1-y})N (1≧x≧0, 1≧y≧0).

6. The light emitting diode of claim 1, wherein the base substrate is made of sapphire having a thickness from 10 um to 500 um.

7. The light emitting diode of claim 1, wherein the first conductive contact layer is p-type and the second conductive contact layer is n-type.

8. The light emitting diode of claim 1, wherein the via hole formed through the base substrate and the buffer layer narrows as it approaches the first conductive contact layer.

9. The light emitting diode of claim 1, wherein the base substrate is provided with prominences and depressions on a surface on which other layers are not formed.

10. The light emitting diode of claim 1, further comprising a lead frame on which the first electrode is borided by means of a conductive paste and to which the second electrode is electrically connected through wire bonding.

11. The light emitting diode of claim 1, further comprising:
an ohmic layer including a reflection layer formed between the first electrode and the second conductive contact layer; and
a transparent conductive layer formed between the second electrode and the first conductive contact layer and expanded outside of the via hole so as to cover a predetermined area of the base substrate.

12. The light emitting diode of claim 11, wherein the transparent conductive layer is formed with at least one among ITO, ZrB, ZnO, InO, SnO, and Inₓ(Ga_{y}Al_{1-y})N.

13. The light emitting diode of claim 1, wherein the first electrode is formed with a transparent conductive material.

14. The light emitting diode of claim 13, further comprising an ohmic layer and a light reflection layer formed between the second electrode and the first conductive contact layer and covering the inner surface of the via hole as well as the surface of the base substrate.

15. The light emitting diode of claim 13, wherein the first electrode is formed with at least one among ITO, ZrB, ZnO, InO, SnO, and Inₓ(Ga_{y}Al_{1-y})N.

16. The light emitting diode of claim 15, wherein the first electrode is formed with Inₓ(Ga_{y}Al_{1-y})N at a thickness of from 0.1 um˜200 um.

17. The light emitting diode of claim 13, further comprising a first electrode pad formed on the first electrode.

18. The light emitting diode of claim 17, further comprising a dielectric layer formed at an area at which the first electrode is removed and which is covered by the first electrode pad.

19. The light emitting diode of claim 13, further comprising a lead frame on which the second electrode is bonded by means of a conductive paste and to which the first electrode is electrically connected through wire bonding.

20. The light emitting diode of claim 1, wherein the first electrode is made of a metal which can form an ohmic layer and in a lattice structure so as to allow penetration of light.

21. The light emitting diode of claim 1, wherein the semiconductor nitride layer is provided with a surface, on an opposite side of the surface on which a nitride semiconductor is formed, having chamfered edges.

22. The light emitting diode of claim 1, wherein the first and second conductive layers and the active layer are formed with Inₓ(Ga_{y}Al_{1-y})N (1≧x≧0, 1≧y≧0).

23. A method for manufacturing a light emitting diode, comprising:
forming a buffer layer, a first conductive contact layer, an active layer, and a second conductive contact layer on a base substrate;
forming a protection film on the second conductive contact layer;
lapping the base substrate;
forming an oxide film (SiO2) on the base substrate;
exposing a part of the base substrate by etching out the oxide film with photolithography;
forming a via hole by etching out the exposed part of the base substrate;
exposing the first conductive contact layer by etching out the buffer layer exposed through the via hole; and
forming a second electrode connected to the first conductive contact layer through the via hole.

24. The method of claim 23, further comprising:
thermal treatment of the base substrate using a furnace having a nitrogen or oxygen atmosphere at temperatures from 500□ to 700□.

25. The method of claim 23, further comprising adhering an auxiliary substrate before lapping the base substrate.

26. The method of claim 25, wherein the auxiliary substrate is one of a dielectric substrate such as sapphire, glass, and quartz; a semiconductor substrate such as Si, GaAs, InP, and InAs; a conductive oxide film such as Indium Tin Oxide (ITO), ZrB, and ZnO; a metal substrate such as CuW, Mo, Au, Al, and Au; and a metal film.

27. The method of claim 26, wherein the metal film is formed by depositing one or more among Au, Cu, Pt, and Ni as a single layer or multiple layers using one or more of electroplating or electroless plating.

28. The method of claim 25, wherein the auxiliary substrate is bonded by thermal pressing using an eutectic metal as an adhesive, and the eutectic metal is made of at least one among In, Au, Sn, Pd, Rh, Ti, Pt, Ni, Au, and Ge.

29. The method of claim 23, wherein etching the oxide film is carried out by a wet etching technique using a BOE solution as the etchant, or by a RIE dry etching technique.

30. The method of claim 23, wherein forming the via hole is carried out by using a mixture solution, as an etchant, containing one or more among hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+H NO₃+H₂O).

31. The method of claim 30, wherein the etchant is used at a temperature over 100□.

32. The method of claim 23, wherein forming a via hole is carried out by using both a wet etching technique using one or a mixture of hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O); and a dry etching technique of ICP/RIE or RIE.

33. The method of claim 32, wherein the wet etching technique is used for etching out the base substrate, and the dry etching technique is used for etching out the nitride semiconductor layer.

34. The method of claim 32, wherein whether or not the first conductive contact layer is exposed is determined by monitoring electrical characteristics in the via hole using a probe.

35. The method of claim 32, wherein a thickness of the base substrate and whether or not the first conductive contact layer is exposed are measured by means of an optical measurement technique using an optical interference principle.

36. The method of claim 32, wherein the dry etching technique uses at least one of BCl₃, Cl₂, HBr, and Ar, as an etching gas.

37. The method of claim 32, wherein etching out the base substrate is carried out using both the dry and wet etching techniques.

38. The method of claim 23, further comprising:
forming a first ohmic layer on the second conductive contact layer before depositing the first electrode; and
forming a second ohmic layer contacting the first conductive contact layer before forming the second electrode.

39. The method of claim 23, wherein an opening exposing the second conductive contact layer is formed in the first electrode during the step of forming the first electrode, the first electrode being formed with a light transmitting conductive material, and it further comprises a step of a first electrode pad contacting the second conductive contact layer on the first electrode.

40. The method of claim 23, wherein at least one of the first and second electrodes is formed by electroplating with at least one among Ti, Au, Cu, Ni, Al, and Ag.

41. The method of claim 23, wherein the first or second electrode is formed by depositing one or more among Ti, Ni, Pt, and Au, and then thermal-treating in a nitrogen or oxygen atmosphere at a temperature over 400° C.

42. The method of claim 23, wherein the first electrode is formed by growing Inₓ(Ga_{y}Al_{1-y})N again at a thickness of from 0.1 um to 200 um.

43. The method of claim 23, wherein lapping and polishing the base substrate are carried out by means of a wet etching technique using one or a mixture of hydrochloric acid (HCl), nitric acid (HNO₃), potassium hydroxide (KOH), sodium hydroxide (NaOH), sulfuric acid (H₂SO₄), phosphoric acid (H₃PO₄) and Aluetch (4H₃PO₄+4CH₃COOH+HNO₃+H₂O), or by chemical mechanical polishing.

44. The method of claim 23, further comprising a step of separating the base substrate into individual chips by performing at least one of a dry etching technique and a wet etching technique.

45. The method of claim 44, wherein separating the base substrate into individual chips is carried out by means of the wet etching technique using one or a mixture of hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O).

46. The method of claim 23, wherein while forming the via hole by etching the exposed area of the base substrate, cleavage lines for separating the base substrate into individual chips and prominences and depressions for facilitating light extraction are formed at the same time.

47. The method of claim 23, further comprising a step of forming an etch stop layer at an area in which the via hole is formed before forming the buffer layer on the base substrate.

48. The method of claim 47, wherein the etch stop layer includes a SiO2 cluster layer or a nitride semiconductor of a Mg-doped p-type Inₓ(Ga_{y}Al_{1-y})N (1≧x≧0, 1≧y≧0).

49. The method of claim 31, wherein lapping the base substrate is carried out so as to make the thickness of the base substrate become 10 um˜200 um.

50. A method for etching a sapphire substrate, comprising:
growing a nitride semiconductor thin layer on the sapphire substrate; and
performing wet etching by immersing the sapphire substrate into an etchant composed of one or a mixture of hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O).

51. The method of claim 50, further comprising a step of dry etching the sapphire substrate by an RIE or ICP/RIE technique.

52. The method of claim 51, wherein the dry etching is performed before the wet etching.

53. The method of claim 50, wherein the etchant of one or the mixture solution of hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O) is heated to over 100° C. during the wet etching process.

54. The method of claim 53, wherein the etchant is heated by an indirect heating technique using optical absorption.

55. A light emitting diode comprising:
a conductive receptor substrate having top and bottom surfaces;
a first electrode formed on the bottom surface of the receptor substrate;
a joint layer formed on the top surface of the receptor substrate and having conductivity;
a first conductive contact layer formed on the joint layer;
an active layer formed on the first conductive contact layer;
a second conductive contact layer formed on the active layer; and
a second electrode formed on the second conductive contact layer.

56. The light emitting diode of claim 55, further comprising a buffer layer formed on the second conductive contact layer and having a via hole exposing the second conductive contact layer and a base substrate formed on the buffer layer and having a via hole overlapping with the via hole of the buffer layer, and wherein the base substrate having a via hole overlapped with the via hole of the buffer layer and the second electrode connected to the second conductive contact layer through the via holes.

57. The light emitting diode of claim 55, further comprising:
a first receptor ohmic contact layer formed between the first electrode and the receptor substrate;
a second receptor ohmic contact layer formed between the receptor and the joint layer; and
a light reflection layer formed between the receptor substrate and the first conductive contact layer.

58. The light emitting diode of claim 57, further comprising:
a conductive transparent electrode formed between the light reflection layer and the first conductive contact layer; and
a second electrode ohmic layer formed between the second electrode and the second conductive contact layer.

59. The light emitting diode of claim 56, wherein the joint layer is formed with a metal containing at least one of Ti, Ni, Sn, In, Pd, Ag, Au, Pt, and Al.

60. The light emitting diode of claim 56, wherein the joint layer is an epoxy film having conductivity.

61. The light emitting diode of claim 56, wherein the first conductive contact layer is p-type, and the second conductive contact layer is n-type.

62. The light emitting diode of claim 56, wherein the conductive receptor substrate is formed with at least one of a semiconductor substrate such as Si, GaP, InP, InAs, GaAs, and SiC; a metal substrate; and a metal film such Au, Al, CuW, Mo, and W.

63. The method of claim 56, wherein the light reflection layer includes at least one of Ni, Al, Ag, Au, Cu, Pt, and Rh.

64. A method for manufacturing a light emitting diode comprising:
depositing, sequentially, a buffer layer, a n-type contact layer, an active layer, and a p-type contact layer on a sapphire base substrate;
forming first and a second receptor contact layers on respective opposite side of a receptor substrate;
forming a joint layer on at least one of a p-type contact layer and the second receptor contact layer;
jointing the sapphire base substrate and the receptor substrate by thermal-compression in a state of facing the p-type contact layer and the second receptor contact layer with each other;
lapping and polishing the sapphire base substrate;
depositing an oxide film (SiO2) on the sapphire base substrate;
exposing a portion of the sapphire base substrate by photo-etching the oxide film;
forming a via hole by etching out the sapphire base substrate; and
forming a second electrode and a first electrode on the n-type contact layer and the first receptor contact layer, respectively.

65. The method of claim 64, further comprising:
exposing the n-type contact layer by etching out the sapphire base substrate after lapping and polishing the sapphire base substrate; and
forming the second electrode and the first electrode on the n-type contact layer and the first receptor contact layer, respectively.

66. The method of claim 65, further comprising a step of forming a conductive transparent electrode layer and a light reflection layer on the p-type contact layer before forming the joint layer on at least one of the p-type contact layer and the second receptor contact layer.

67. The method of claim 65, wherein etching the sapphire base substrate is carried out by means of at least one among a wet etching technique with one or a mixture of hydrochloric acid (HCl), nitric acid (HNO₃), potassium hydroxide (KOH), sodium hydroxide (NaOH), sulfuric acid (H₂SO₄), phosphoric acid (H₃PO₄), and Aluetch (4H₃PO₄+4CH₃COOH+HNO₃+H₂O); a chemical mechanical polishing (CMP) technique; and an ICP/RIE dry etching technique.

68. The method of claim 67, wherein removing the sapphire base substrate and the buffer layer is carried out by both of the wet etching technique and the dry etching technique, the wet etching technique being used for etching out the sapphire base substrate and the dry etching technique being used for etching out the buffer layer.

69. The method of claim 64, wherein thermal-compression is carried out in vacuum or in a gaseous atmosphere including at least one among Ar, He, Kr, Xe, and N2.

70. The method of claim 64, wherein thermal-compression is carried out at temperatures from 200□ to 600□ at a pressure between 1 MPa and 6 Mpa for 1˜60 minutes.

71. A method for manufacturing a light emitting diode, comprising:
depositing, sequentially, a buffer layer, a n-type contact layer, an active layer, and a p-type contact layer on a sapphire base substrate;
lapping and polishing the sapphire base substrate;
depositing an oxide film (SiO2) on the sapphire base substrate;
exposing a portion of the sapphire base substrate by photo-etching the oxide film;
forming a via hole by etching out the sapphire base substrate; and
forming, sequentially, an ohmic contact layer and a seed metal on the p-type contact layer; and
forming a receptor metal layer on the seed metal by means of electroplating or an electroless plating technique.

72. The method of claim 71, wherein the ohmic layer and seed metal are formed as a single layer or multiple layers including at least one of Pt, Ni, Cu, and Au; and the receptor metal layer is formed as a single layer or multiple layers including at least one of Au, Cu, Pt, and Ni.
